(19) United States
(12) Patent Application Publication
(10) Pub. No.: US 2014/0253856 A1
(43) Pub. Date: Sep. 11, 2014

(54) DISPLAY UNIT, METHOD OF MANUFACTURING DISPLAY UNIT, AND ELECTRONIC APPARATUS

(71) Applicant: Sony Corporation, Tokyo (JP)

(72) Inventor: Yuji NAKAHATA, Tokyo (JP)

(73) Assignee: Sony Corporation, Tokyo (JP)

(21) Appl. No.: 14/189,563

(22) Filed: Feb. 25, 2014

(30) Foreign Application Priority Data
Mar. 8, 2013 (JP) 2013-046575

(51) Int. Cl. G02F 1/1339; H01L 33/08; H01L 27/32

(52) U.S. Cl. CPC G02F 1/1339; H01L 27/3244; H01L 33/08
USPC 349/139; 257/40; 438/34; 257/88

(57) ABSTRACT

Provided is a method of manufacturing a display unit that includes: forming a plurality of first electrodes for respective pixels; forming a display function layer; forming a second electrode configured to apply, together with the first electrodes, a drive voltage to the display function layer; forming a third electrode disposed facing the second electrode, and electrically connected to the second electrode; and forming a first spacer and a second spacer between the second electrode and the third electrode, in which the second spacer has a height that is lower than a height of the first spacer. The second electrode and the third electrode are electrically connected to one another in a path that includes the first spacer, and are electrically insulated from one another in a path that includes the second spacer.

### CROSS REFERENCES TO RELATED APPLICATIONS

The present application claims priority to Japanese Priority Patent Application JP 2013-046575 filed in the Japan Patent Office on Mar. 8, 2013, the entire content of which is hereby incorporated by reference.

### BACKGROUND

The present disclosure relates to a display unit having a structure in which display elements are sealed, for example, by using spacers, to a method of manufacturing the display unit, and to an electronic apparatus.

In an organic EL (Electro Luminescence) display unit, an electrode having high wiring resistance such as a transparent conductive film is used. This causes a so-called voltage drop and decrease in display quality. To address such an issue, there is a method in which, to reduce such wiring resistance, wiring is separately provided on the sealing substrate side, and a transparent conductive film is electrically connected to the wiring (for example, see Japanese Unexamined Patent Application Publication No. 2011-103205).

In Japanese Unexamined Patent Application Publication No. 2011-103205, an upper electrode configured of the transparent conductive film and metal wiring are provided on the sealing substrate. Further, the upper electrode and the metal wiring are electrically connected to each other by using conductive spacers. In addition, for example, a sealing material is filled in the space (void) formed by the spacers, and thereby the filled void functions as a sealing layer of display elements. Thus, a structure is achieved in which, by using the conductive spacers, element sealing is performed and wiring resistance is reduced.

### SUMMARY

However, a thickness of a void in which a sealing material is filled or a pressure applied to a display panel is not even in a panel surface. Accordingly, there is desired a realization of a display unit that has a high reliability and reduces a wiring resistance while having mechanical flexibility (durability) to uneven thickness or a local pressure.

It is desirable to provide a display unit, a method of manufacturing the display unit, and an electronic apparatus that are capable of improving reliability.

A display unit according to an embodiment of the present disclosure includes: a plurality of first electrodes provided for respective pixels; a display function layer provided on the first electrodes; a second electrode configured to apply, together with the first electrodes, a drive voltage to the display function layer; a third electrode disposed facing the second electrode, and electrically connected to the second electrode; a first spacer arranged between the second electrode and the third electrode; and a second spacer arranged between the second electrode and the third electrode, and having a height that is lower than a height of the first spacer. The second electrode and the third electrode are electrically connected to one another in a path that includes the first spacer, and are electrically insulated from one another in a path that includes the second spacer.

A method of manufacturing a display unit according to an embodiment of the present disclosure includes: forming a plurality of first electrodes for respective pixels; forming a display function layer; forming a second electrode configured to apply, together with the first electrodes, a drive voltage to the display function layer; forming a third electrode disposed facing the second electrode, and electrically connected to the second electrode; and forming a first spacer and a second spacer between the second electrode and the third electrode, in which the second spacer has a height that is lower than a height of the first spacer. The second electrode and the third electrode are electrically connected to one another in a path that includes the first spacer, and are electrically insulated from one another in a path that includes the second spacer.

An electronic apparatus according to an embodiment of the present disclosure is with a display unit that includes: a plurality of first electrodes provided for respective pixels; a display function layer provided on the first electrodes; a second electrode configured to apply, together with the first electrodes, a drive voltage to the display function layer; a third electrode disposed facing the second electrode, and electrically connected to the second electrode; a first spacer arranged between the second electrode and the third electrode; and a second spacer arranged between the second electrode and the third electrode, and having a height that is lower than a height of the first spacer. The second electrode and the third electrode are electrically connected to one another in a path that includes the first spacer, and are electrically insulated from one another in a path that includes the second spacer.

In the display unit, the method of manufacturing the display unit, and the electronic apparatus according to the above-described respective embodiments of the present disclosure, the third electrode is provided that is disposed facing the second electrode configured to apply, together with the first electrodes, the drive voltage to the display function layer, and electrically connected to the second electrode. These second electrode and third electrode are electrically connected to one another in the path that includes the first spacer, and are electrically insulated from one another in the path that includes the second spacer that has the height lower than the height of the first spacer. Thereby, mainly by the first spacer, a thickness of space (void) between the second electrode and the third electrode is controlled, and electrical conduction between the second electrode and the third electrode is secured. Also, when a pressure is applied to a local region of a panel, a load due to the pressure is mainly absorbed by the second spacer, and the load applied to the first spacer is reduced. Further, the second electrode and the third electrode are electrically insulated from one another in the path that includes the second spacer. Thus, a resistance is difficult to be varied depending on the presence or absence of contact between the second spacer and the second and the third electrodes. Hence, while mechanical flexibility (durability) is kept, wiring resistance is reduced and variation in the wiring resistance is suppressed in a panel surface.

According to the display unit, the method of manufacturing the display unit, and the electronic apparatus in the above-described respective embodiments of the present disclosure, the third electrode is disposed facing the second electrode that is configured to apply, together with the first electrodes, the drive voltage to the display function layer, and is electrically connected to the second electrode. The second electrode and the third electrode are electrically connected to one another in the path that includes the first spacer, and are electrically insulated from one another in the path that includes the second spacer having the height lower than the height of the first spacer. Accordingly, while mechanical flexibility (durability) is kept, wiring resistance is reduced and variation in the wiring resistance is suppressed in a panel surface. Therefore, it is possible to improve reliability.

It is to be understood that both the foregoing general description and the following detailed description are exemplary, and are intended to provide further explanation of the technology as claimed.

Additional features and advantages are described herein, and will be apparent from the following Detailed Description and the figures.

### BRIEF DESCRIPTION OF THE FIGURES

The accompanying drawings are included to provide a further understanding of the disclosure, and are incorporated in and constitute a part of this specification. The drawings illustrate embodiments and, together with the specification, serve to explain the principles of the technology.

FIG. 1 is a cross-sectional view illustrating a configuration of an organic EL display unit according to an embodiment of the present disclosure.

FIG. 2A is a schematic plan view illustrating an example of an arrangement configuration of spacers and an auxiliary wiring layer illustrated in FIG. 1.

FIG. 2B is a schematic plan view illustrating an example of an arrangement configuration of the spacers and the auxiliary wiring layer illustrated in FIG. 1.

FIG. 3A is a cross-sectional view for describing a formation process of a device substrate illustrated in FIG. 1.

FIG. 3B is a cross-sectional view illustrating a process following the process illustrated in FIG. 3A.

FIG. 3C is a cross-sectional view illustrating a process following the process illustrated in FIG. 3B.

FIG. 3D is a cross-sectional view illustrating a process following the process illustrated in FIG. 3C.

FIG. 3E is a cross-sectional view illustrating a process following the process illustrated in FIG. 3D.

FIG. 3F is a cross-sectional view illustrating a process following the process illustrated in FIG. 3E.

FIG. 3G is a cross-sectional view illustrating a process following the process illustrated in FIG. 3F.

FIG. 4A is a cross-sectional view for describing a formation process of a sealing substrate illustrated in FIG. 1.

FIG. 4B is a cross-sectional view illustrating a process following the process illustrated in FIG. 4A.

FIG. 4C is a cross-sectional view illustrating a process following the process illustrated in FIG. 4B.

FIG. 4D is a cross-sectional view illustrating a process following the process illustrated in FIG. 4C.

FIG. 5 is a schematic view for describing an effect of the display unit illustrated in FIG. 1.

FIG. 6 is a cross-sectional view illustrating a configuration of the sealing substrate and the auxiliary wiring layer according to modification example 1.

FIG. 7 is a cross-sectional view illustrating a configuration of the sealing substrate and the auxiliary wiring layer according to modification example 2.

FIG. 8 is a cross-sectional view illustrating a configuration of the sealing substrate and the auxiliary wiring layer according to modification example 2.

FIG. 9A is a cross-sectional view illustrating a configuration of the sealing substrate and the auxiliary wiring layer according to modification example 3-1.

FIG. 9B is a cross-sectional view illustrating a configuration of the sealing substrate and the auxiliary wiring layer according to modification example 3-2.

FIG. 10A is a cross-sectional view illustrating a configuration of the sealing substrate and the auxiliary wiring layer according to modification example 4-1.

FIG. 10B is a cross-sectional view illustrating a configuration of the sealing substrate and the auxiliary wiring layer according to modification example 4-2.

FIG. 11 is a cross-sectional view illustrating a configuration of the sealing substrate and the auxiliary wiring layer according to modification example 5.

FIG. 12 is a schematic plan view illustrating an example of an arrangement configuration of the spacers and the auxiliary wiring layer illustrated in FIG. 11.

FIG. 13 is a schematic view for describing an example of a preferable arrangement of the spacers according to modification example 6.

FIG. 14A is a schematic view for describing an arrangement example of the spacers according to modification example 7.

FIG. 14B is a schematic view for describing an arrangement example of the spacers in another pixel arrangement of FIG. 14A.

FIG. 15 is a cross-sectional view illustrating a configuration of a liquid crystal display unit according to modification example 8.

FIG. 16 illustrates an overall configuration including peripheral circuits of the display unit according to any of the example embodiments.

FIG. 17 illustrates a circuit configuration of pixels illustrated in FIG. 16.

FIG. 18 is a plan view illustrating an outline configuration of a module including the display unit illustrated in FIG. 16.

FIG. 19 is a perspective view illustrating an appearance of application example 1.

FIG. 20A is a perspective view illustrating an appearance viewed from a front side of application example 2.

FIG. 20B is a perspective view illustrating an appearance viewed from a rear side of application example 2.

FIG. 21 is a perspective view illustrating an appearance of application example 3.

FIG. 22 is a perspective view illustrating an appearance of application example 4.

FIG. 23A is a front view in an open state of application example 5, FIG. 23B is a side view thereof, FIG. 23C is a front view in a closed state of the application example 5, FIG. 23D is a left side view thereof, FIG. 23E is a right side view thereof, FIG. 23F is a top view thereof, and FIG. 23G is a bottom view thereof.

FIG. 24A is a perspective view illustrating an appearance of application example 6.

FIG. 24B is a perspective view illustrating an appearance of application example 6.

### DETAILED DESCRIPTION

Hereinafter, some example embodiments of the present disclosure are described in detail with reference to the accompanying drawings. The description will be given in the following order.

1. Embodiment (Example of an organic EL display unit in which first and second spacers are formed by an insulating material, the first spacer having a higher height is covered with a conductive film, and the conductive film facing the second spacer having a lower height is selectively removed)
2. Modification Example 1 (Example where a region of an auxiliary wiring layer facing the second spacer is selectively removed)
3. Modification Example 2 (Example where a foundation layer of the first spacer is formed by using a laminated film of a color filter layer)
4. Modification Example 3-1 (Example where a region of a second electrode facing the second spacer (electrically conductive) is selectively removed)
5. Modification Example 3-2 (Example where a region of the auxiliary wiring layer facing the second spacer (electrically conductive) is selectively removed)
6. Modification Example 4-1 (Example where an insulating film is provided on a surface of the second spacer (electrically conductive) facing the auxiliary wiring layer)
7. Modification Example 4-2 (Example where an insulating film is provided on a surface of the auxiliary wiring layer facing the second spacer (electrically conductive))
8. Modification Example 5 (Example of a case where the first spacer and the second spacer are integrally formed)
9. Modification Example 6 (Example of preferred arrangement of the first spacer and the second spacer)
10. Modification Example 7 (Example of a spacer arrangement in a four-pixel configuration of R, G, B, and W)
11. Modification Example 8 (Example of a liquid crystal display unit)
12. Example of an overall configuration of a display unit and example of a pixel circuit configuration
13. Application examples (Application examples to an electronic apparatus)

### Embodiment

### Configuration

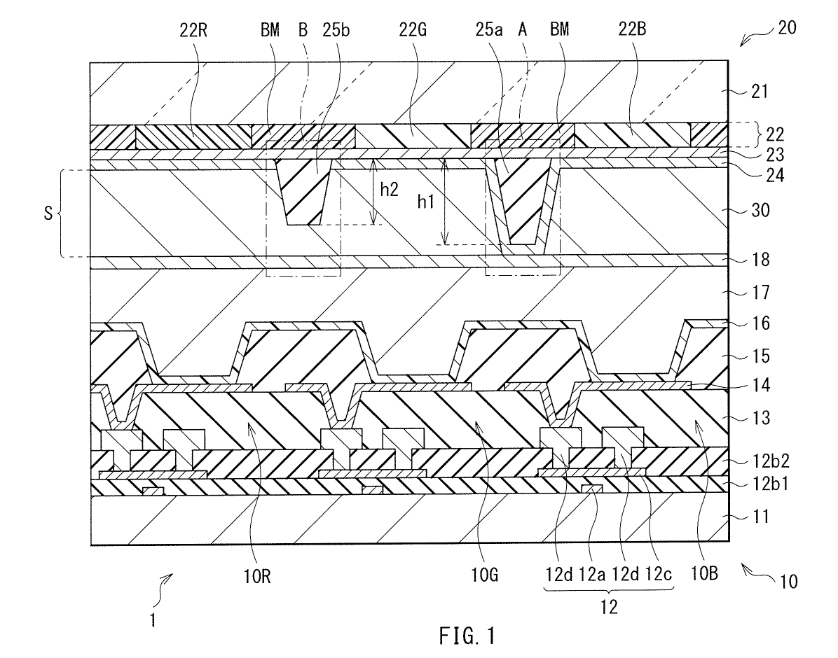

FIG. 1 illustrates a cross-sectional configuration of an organic EL display unit (organic EL display unit 1) according to an embodiment of the present disclosure. In the organic EL display unit 1, for example, a sealing substrate 20 may be bonded through a sealing layer 30 on a device substrate 10 on which organic EL elements 10R, 10G, 10B, and TFTs 12 as pixels are formed. This organic EL display unit 1 is a top emission type organic EL display unit in which light is taken out from an upper region of the sealing substrate 20. In this organic EL display unit 1, for example, the organic EL element 10R is a sub-pixel that emits red (R) light, the organic EL element 10G is a sub-pixel that emits green (G) light, and the organic EL element 10B is a sub-pixel that emits blue (B) light. Further, one pixel is configured by the three organic EL elements 10R, 10G, and 10B.

(Device Substrate 10)

In the device substrate 10, the plurality of organic EL elements 10R, 10G, and 10B may be arranged in matrix, for example, as pixels forming a display region (a display region 110 to be hereinafter described). In the device substrate 10, for example, a gate electrode 12a, a semiconductor layer 12c, and a source/drain electrode 12d are formed as the TFT 12 on the first substrate 11. A gate insulating film 12b1 is formed between the gate electrode 12a and the semiconductor layer 12c. The semiconductor layer 12c is covered by an interlayer insulating film 12b2. Further, the source/drain electrode 12d is connected to the semiconductor layer 12c through a contact hole of the interlayer insulating film 12b2.

The first substrate 11 may be a glass substrate or a plastic substrate, for example. Examples of the glass substrate may include a high strain point glass, soda-lime glass (Na₂O.CaO.SiO₂), borosilicate glass (Na₂O.B₂O₃.SiO₂), forsterite (2MgO.SiO₂), lead glass (Na₂O.Pb.SiO₂), and the like. Alternatively, the substrate may be made of quartz, silicon, or a metal whose surface is formed with an insulating film. Examples of the plastic substrate may include an organic polymer such as polymethyl methacrylate (polymethylmethacrylate, PMMA), polyvinyl alcohol (PVA), polyvinyl phenol (PVP), polyethersulfone (PES), polyimide (PI), polycarbonate (PC), polyethylene terephthalate (PET), and the like. Note that the plastic substrate encompasses a film-shaped or a sheet-shaped substrate having flexibility.

The TFT 12, for example, corresponds to transistors 3A and 3B in a pixel circuit 60 to be described later. A configuration of the TFT 12 may be, for example, an inverted-staggered structure (bottom-gate structure), or a staggered structure (top-gate structure).

The organic EL elements 10R, 10G, and 10B each may have, for example, a first electrode 14, an organic layer 16 including a light emitting layer, a resistive layer 17, and a second electrode 23. The first electrode 14 is electrically connected to the TFT 12 (in detail, the source/drain electrode 12d) through the contact hole that is provided on an interlayer insulating film 13. In each of the organic EL elements 10R, 10G, and 10B, an element isolation is made by the interlayer insulating film 13 and an inter-pixel insulating film 15 formed on the first electrode 14. Specifically, an opening H is formed on the inter-pixel insulating film 15 while facing the first electrode 14, and the first electrode 14, the organic layer 16, and the resistive layer 17 are laminated in the opening H. The second electrode 23 is provided on the sealing substrate 20 side (to be described later in detail).

The first electrode 14 is provided for each of the organic EL elements 10R, 10G, and 10B. A constituent material of the first electrode 14, in the case of serving as an anode, for example, may be a simple substance of a metal having a high work function such as platinum (Pt), gold (Au), silver (Ag), chromium (Cr), tungsten (W), nickel (Ni), copper (Cu), iron (Fe), cobalt (Co), tantalum (Ta), and the like, or an alloy thereof. Examples of the alloy may include Ag—Pd—Cu alloy and Al—Nd alloy. Alternatively, the first electrode 14 may have a laminated structure including a metal film that contains a simple substance or an alloy of the above-described metal elements, and a transparent conductive film such as ITO and the like. The first electrode 14 may be preferably made of a material having a high hole injection property; however, even if the first electrode 14 is made of a material does not involve high hole injection property (aluminum (Al), an alloy including aluminum, or the like), the first electrode 14 may be used as an anode by providing an appropriate hole injection layer. A thickness of the first electrode 14 may be, for example, from 10 nm to 1000 nm. In the case of a bottom emission type, the first electrode 14 may be made of a transparent conductive film, for example, a single layer film including any one or a laminated film including two kinds or more of an oxide of indium and tin (ITO), an indium zinc oxide (IZO), and an alloy of a zinc oxide (ZnO) and aluminum (Al).

The inter-pixel insulating film 15 secures an insulation property between the first electrode 14 and the second electrode 23 of the organic EL elements 10R, 10G, and 10B, and partitions (separates) the respective pixel regions. The inter-pixel insulating film 15 may be preferably made of an insulating material having superior planarization property and having a low coefficient of water absorption for preventing deterioration of the organic layer 16 due to moisture and keeping light emission luminance. Example of such insulating material may include, for example, polyimide resin, acrylate resin, novolac resin, and the like,

The organic layer 16 includes at least an organic electroluminescence layer (hereinafter, simply referred to as a luminescence layer). In this embodiment, the luminescence layer (for example, a white luminescence layer) is formed as a common layer to all pixels. Examples of the white luminescence layer may include a layer in which a blue luminescence layer and a yellow luminescence layer are laminated, and a layer in which blue, green, and red luminescence layers are laminated. The red luminescence layer may be a layer that includes at least one of a red light-emitting material, a hole transport material, and an electron transport material, and may have a configuration in which, for example, 2,6-bis[(4′-methoxydiphenylamino) styryl]-1,5-dicyanonaphthalene (BSN) is mixed with 4,4-bis (2, 2-diphenylvinylene) biphenyl (DPVBi). The green luminescence layer may be a layer that includes at least one of a green light-emitting material, a hole transport material, and an electron transport material, and may have a configuration in which, for example, coumalin 6 is mixed with ADN or DPVBi. The blue luminescence layer may be a layer that includes at least one of a blue light-emitting material, a hole transport material, and an electron transport material, and may have a configuration in which, for example, 4,4′-bis[2-{4-(N,N-diphenylamino) phenyl}vinyl]biphenyl (DPAVBi) is mixed with DPVBi. Besides such a light emitting layer, for example, the organic layer 16 may have a configuration in which a hole injection layer, a hole transport layer, an electron transport layer, and the like are laminated.

The resistive layer 17 is formed between the organic layer 16 and the second electrode 23, and may be made of a transparent material having a high electric resistivity, such as niobium oxide (Nb₂O₅), ITO, or IZO. Providing the resistive layer 17 suppresses an occurrence of a short circuit, for example, due to foreign substances between the first electrode 14 and the second electrode 23 when a voltage is applied between the first electrode 14 and the second electrode 23, making it possible to prevent the occurrence of a defective pixel or a missing line. Note that, the resistive layer 17 may be provided on an as-necessary basis, and the auxiliary wiring layer 18 may be formed on the organic layer 16.

The second electrode 23 is electrically connected to the organic layer 16 through the resistive layer 17, and may be commonly provided, for example, for the plurality of organic EL elements 10R, 10G, and 10B. In the present embodiment, since the organic EL display unit 1 is a top emission type organic EL display unit, the second electrode 23 is made of the transparent conductive film. The transparent conductive film may be a single layer film including any one or a laminated film including two kinds or more of an oxide of indium and tin (ITO), InZnO (indium zinc oxide), and an alloy of zinc oxide (ZnO) and aluminum (Al). In the present embodiment, as described later, the second electrode 23 is arranged not for the device substrate 10 but for the sealing substrate 20.

(Sealing Substrate 20)

In the sealing substrate 20, a color filter layer 22 including a red filter layer 22R, a green filter layer 22G, a blue filter layer 22B, and a black matrix layer BM is formed on one surface (surface on the device substrate 10 side) of the second substrate 21. The second electrode 23 is provided between the color filter layer 22 and the sealing layer 30.

The second substrate 21 is made of the similar constituent material to that of the above-described first substrate 11. The second substrate 21 may be made of the same material as or a material different from that of the first substrate 11, so long as the material has transparency.

Each of the red filter layer 22R, the green filter layer 22G, and the blue filter layer 22B is a color filter that selectively transmits light in a specific wavelength region (absorbs light in other wavelength regions). Thereby, in each pixel, white light emitted from the organic layer 16 is emitted as color light of R, G, or B. For example, the red filter layer 22R, the green filter layer 22G, and the blue filter layer 22B each may have a configuration in which a photosensitive resin is mixed with dye or pigment.

(Sealing Layer 30)

Since the second electrode 23 made of the transparent conductive film has high resistance, the second electrode 23 is electrically connected to the auxiliary wiring layer 18 (third electrode) in order to suppress a voltage drop. In the present embodiment, the auxiliary wiring layer 18 is provided on the resistive layer 17 of the device substrate 10 while facing the second electrode 23. Between the second electrode 23 and the auxiliary wiring layer 18, a spacer 25a (first spacer) and a spacer 25b (second spacer) are arranged. In the space (void S) between the second electrode 23 and the auxiliary wiring layer 18 (namely, between the device substrate 10 and the sealing substrate 20), for example, a sealing resin is filled, thereby forming the sealing layer 30.

The sealing layer 30 functions, for example, as a bonding layer for bonding the device substrate 10 and the sealing substrate 20. The sealing layer 30 is also formed for the purpose of preventing intrusion of moisture to the organic layer 16 from the outside and for increasing mechanical strength. For the sealing layer 30, a resin having, for example, an ultraviolet (UV) curing property or a thermosetting property, and having an electrical insulation property may be used.

In the following, a case where the auxiliary wiring layer 18 is provided on the device substrate 10 side and the second electrode 23 is provided on the sealing substrate 20 side is given as an example. The auxiliary wiring layer 18 and the second electrode 23 may be arranged to face each other through the sealing layer 30, and a lamination order may be reversed. That is, for example, the second electrode 23 may be provided on the resistive layer 17, and the auxiliary wiring layer 18 may be provided on the second electrode 23 through the sealing layer 30.

The auxiliary wiring layer 18 reduces a wiring resistance of the second electrode 23, and a potential thereof is kept at the same potential as that of the second electrode 23 (electrically connected to the second electrode 23). The auxiliary wiring layer 18, for example, may be preferably configured by a conductive film having resistance lower than that of the transparent conductive film configuring the second electrode 23. Examples of such conductive film may include at least one of aluminum (Al), silver (Ag), gold (Au), copper (Cu), chromium (Cr), zinc (Zn), iron (Fe), tungsten (W), cobalt (Co), and the like. Note that when the auxiliary wiring layer 18 that is brought into conduction to the second electrode 23 is provided, the electrical resistance is reduced as compared to a case where the auxiliary wiring layer 18 is not provided. Therefore, the auxiliary wiring layer 18 may be configured, for example, by the above-described transparent conductive film.

The spacers 25a and 25b each control a gap between the device substrate 10 and the sealing substrate 20, namely, a thickness (distance of the void S) of the sealing layer 30. The spacer 25a and the spacer 25b have different heights from one another, and a height h2 of the spacer 25b is lower than a height h1 of the spacer 25a (h1>h2). In consideration of the wiring resistance, mechanical flexibility, and the like to be necessary, the heights h1 and h2 of the spacers 25a and 25b may be set as appropriate in accordance with elasticity of constituent materials, arrangement density, the number of spacers to be provided, and the like of the spacers 25a and 25b. In the present embodiment, the spacers 25a and 25b each may be made, for example, of an insulating material such as a photosensitive acrylic resin or the like. Here, the spacers 25a and 25b are arranged adjacent to the second electrode 23 (on the second electrode 23); however, they are not limited thereto. The spacers 25a and 25b may be arranged adjacent to the auxiliary wiring layer 18.

In the spacers 25a and 25b having the heights different from one another, the second electrode 23 and the auxiliary wiring layer 18 are electrically connected to one another in a path (path A) that includes the spacer 25a having the higher height. On the other hand, the second electrode 23 and the auxiliary wiring layer 18 are electrically insulated from one another in a path (path B) that includes the spacer 25b having the lower height. In the present embodiment, specifically, the conductive film 24 is formed to cover at least a part of a surface of each of the spacers 25a and 25b. In the conductive film 24, only a region facing the spacer 25b is selectively removed. Thereby, the auxiliary wiring layer 18 is electrically connected to the second electrode 23 through the conductive film 24 at a location where the spacer 25a is provided (the detail is described later). On the other hand, in a location where the spacer 25b is provided, the auxiliary wiring layer 18 and the second electrode 23 are electrically insulated from one another regardless of the presence or absence of the contact between the spacer 25b and the auxiliary wiring layer 18.

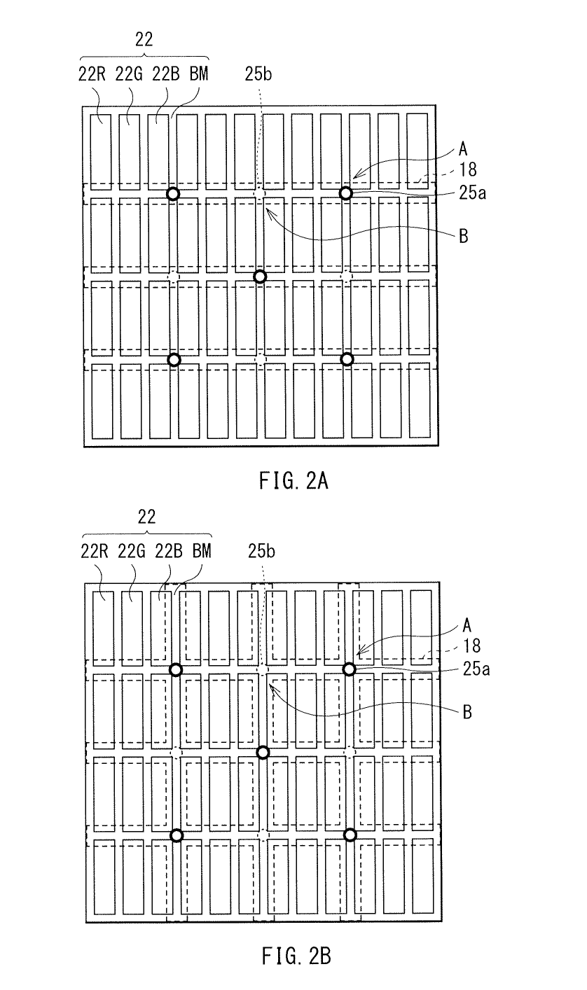

FIGS. 2A and 2B each illustrate an example of an arrangement configuration of the color filter layer 22, the auxiliary wiring layer 18, and the spacers 25a and 25b. In the color filter layer 22, when viewed in a plain surface along a display surface of a panel, the black matrix layer BM is formed so as to surround each of the red filter layer 22R, the green filter layer 22G, and the blue filter layer 22B that are arranged side-by-side. Also, the auxiliary wiring layer 18 (in the drawing, denoted by a broken line) is arranged in a stripe pattern (FIG. 2A) or in a lattice pattern (FIG. 2B) while facing the black matrix layer BM.

The locations where the spacers 25a and 25b are provided are not particularly limited to those illustrated in the drawing. However, at least the spacer 25a is provided in a region facing the auxiliary wiring layer 18 because the electrical conduction between the auxiliary wiring layer 18 and the second electrode 23 is secured mainly by the spacer 25a.

The conductive film 24 is formed to electrically connect the auxiliary wiring layer 18 and the second electrode 23. A constituent material of the conductive film 24 is not particularly limited. However, when the conductive film 24 is formed to cover not only a surface of the spacer 25a but also the red filter layer 22R, the green filter layer 22G, and the blue filter layer 22B, a transparent conductive film such as ITO or the like may be used. Alternatively, when the conductive layer 24 is formed only in a region facing the black matrix layer BM, the metal material exemplified as the constituent material of the above-described auxiliary wiring layer 18 may be used besides the transparent conductive film. In either case, the conductive film 24 covers a surface of the spacer 25a, and a region facing the spacer 25b is selectively removed. Note that, it is unnecessary to cover the entire surface of the spacer 25a. That is, a part (for example, a region facing a side surface of the spacer 25a) of the conductive film 24 may be removed so long as the electrical conduction between the auxiliary wiring layer 18 and the second electrode 23 is secured. Further, in the conductive film 24, it is unnecessary to remove entire part of the region (region covering the spacer 25b) facing the spacer 25b (i.e., it is unnecessary to expose the entire surface of the spacer 25b from the conductive film 24). That is, a part of the surface of the spacer 25b may be covered by the conductive film 24, so long as the auxiliary wiring layer 18 and the second electrode 23 are not electrically conducted by the contact between the auxiliary wiring layer 18 and the spacer 25b.

[Manufacturing Method]

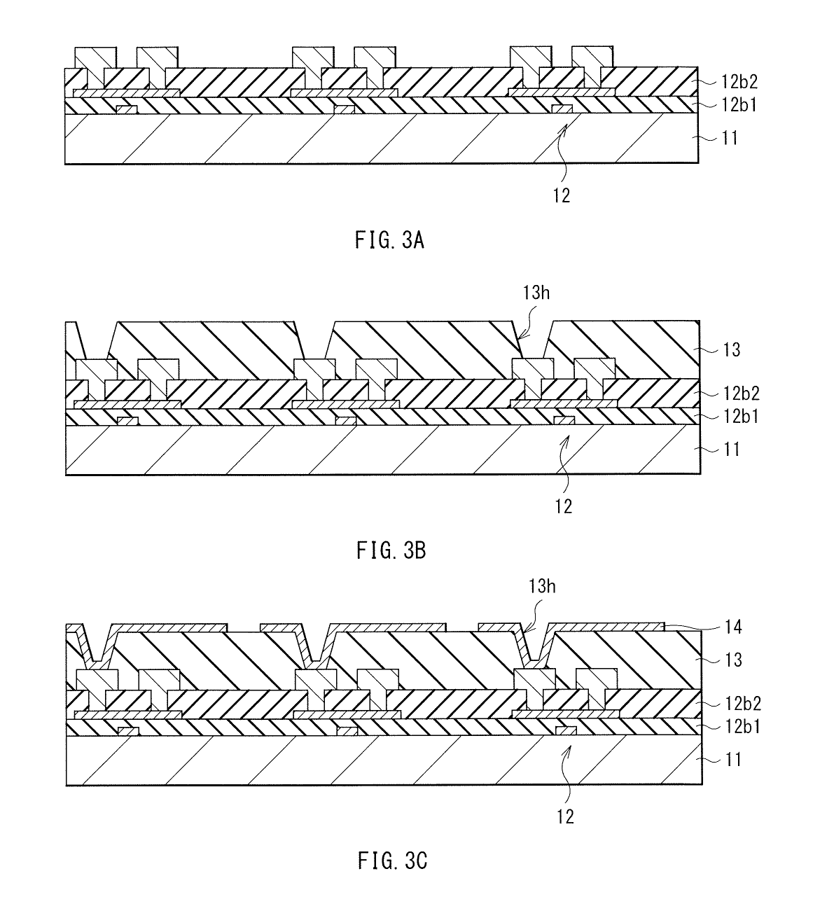

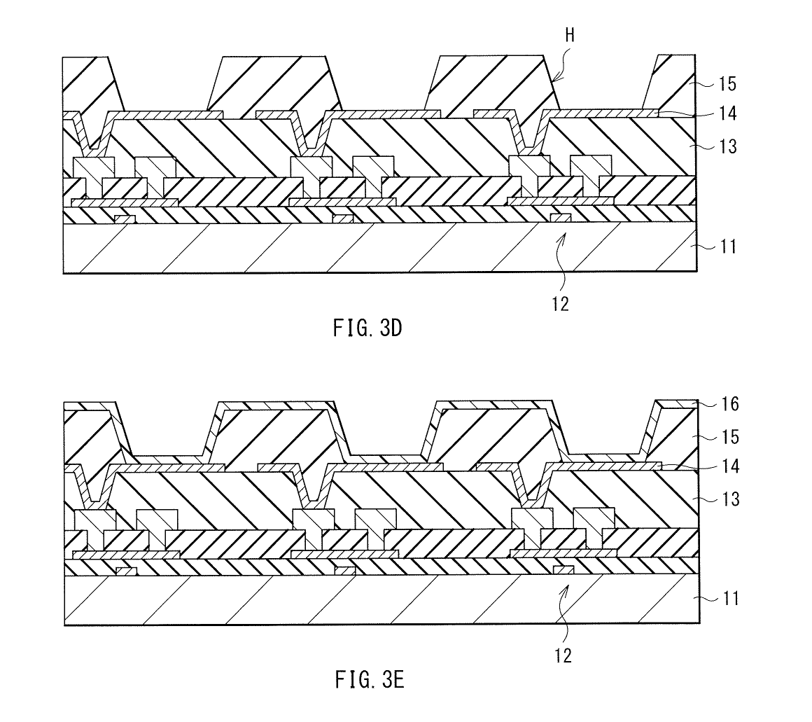

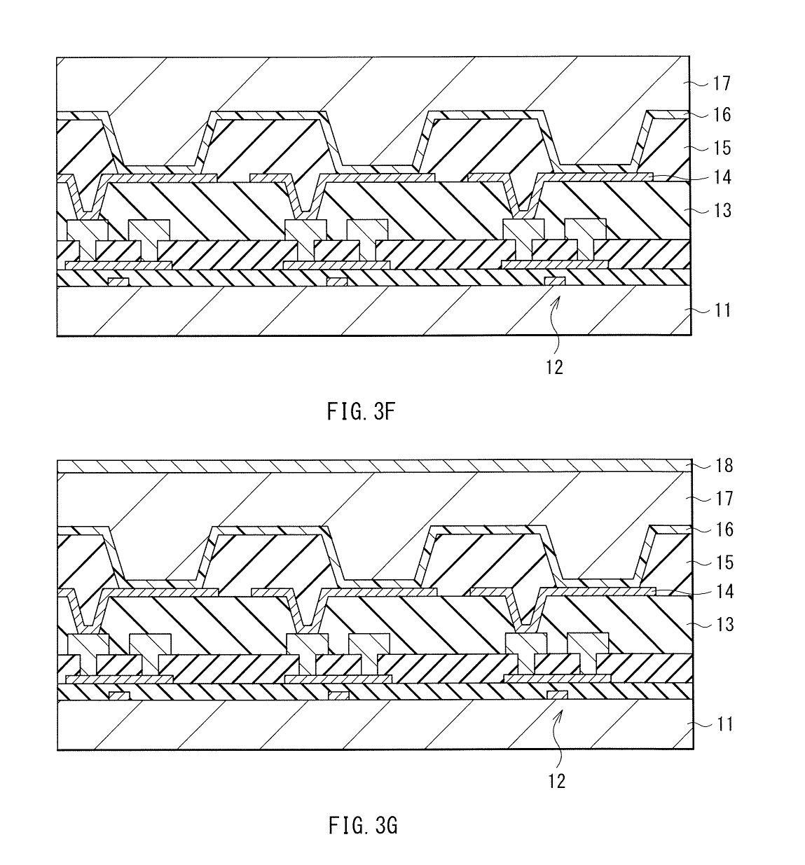

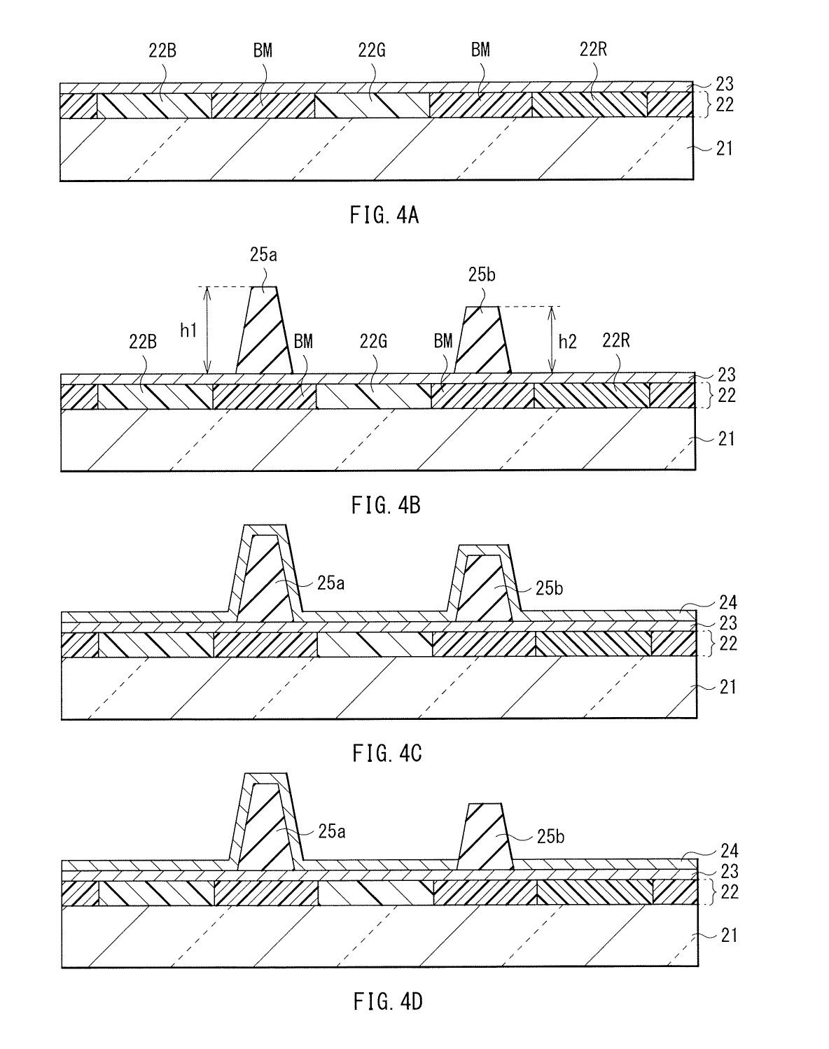

The above-described organic EL display unit 1 may be manufactured as follows, for example. FIGS. 3A to 3G and FIGS. 4A to 4D illustrate a manufacturing process of the organic EL display unit 1.

[Fabrication of Device Substrate 10]

The device substrate 10 may be fabricated, for example, as follows. First, as illustrated in FIG. 3A, by using a known thin-film formation process, the gate electrode 12a, the gate insulating film 12b1, the semiconductor layer 12c, the interlayer insulating film 12b2, the source/drain electrode 12d, and the like are sequentially formed on the first substrate 11, and thereby the TFT 12 is formed.

Then, as illustrated in FIG. 3B, the interlayer insulating film 13 is formed. Specifically, over an entire surface of the first substrate 11, the interlayer insulating film 13 is formed, for example, by using a CVD method, a coating method, a sputtering method, various printing methods, or the like. Then, a contact hole 13h is formed on a region facing the source/drain electrode 12d of the interlayer insulating film 13, for example, through etching using a photolithography method.

Then, as illustrated in FIG. 3C, the first electrode 14 is formed. Specifically, the first electrode 14 made of the above-described material is formed on the interlayer insulating film 13 so as to embed the contact hole 13h, for example, by using the sputtering method. Then, the thus-formed first electrode 14 is patterned in a predetermined shape to be separated for each pixel, for example, through the etching using the photolithography method.

Then, as illustrated in FIG. 3D, the inter-pixel insulating film 15 is formed. Specifically, over the entire surface of the first substrate 11, the inter-pixel insulating film 15 made of the above-described material is formed, following which the opening H is formed at a region corresponding to the first electrode 14. On this occasion, when a photosensitive resin is used for the inter-pixel insulating film 15, the opening H may be formed by exposure using a photomask after the formation thereof. Further, after the opening H is formed, reflow may be performed, if necessary.

Then, as illustrated in FIG. 3E, the organic layer 16 is formed. In the present embodiment, as described above, since the luminescence layer (for example, the white luminescence layer) common to each pixel is formed, respective luminescence materials of red, green, and blue, for example, are sequentially formed over the entire surface of the substrate, for example, by using a vacuum evaporation method. Alternatively, as a formation method of the organic layer 16, a printing method such as a screen printing method and an ink-jet printing method, or a coating method may be used besides the vacuum evaporation method. Further, a laser transfer method may be used in which a laminator including a laser beam absorption layer and an organic layer is previously formed on a transfer substrate, and the transfer substrate is irradiated with a laser to separate the organic layer from the transfer substrate so as to transfer the organic layer. As the organic layer 16, when a hole transport layer, an electron transport layer, and the like are formed besides the above-described luminescence layer, any layer may be preferably formed along with the luminescence layer by using a vacuum consistent process.

Then, as illustrated in FIG. 3F, the resistive layer 17 made of the above-described material is formed over the entire surface of the organic layer 16, for example, by using a sputtering method, an evaporation method, a CVD method, or the like.

Then, as illustrated in FIG. 3G, the auxiliary wiring layer 18 made of the above-described material is formed over the entire surface of the substrate, for example, by using the sputtering method, and then is patterned, for example, through the etching using the photolithography method. In this manner, the device substrate 10 and the auxiliary wiring layer 18 are formed.

(Fabrication of Sealing Substrate 20)

The sealing substrate 20 may be fabricated, for example, as follows. First, as illustrated in FIG. 4A, the color filter layer 22 is formed on the second substrate 21. Specifically, the black matrix layer BM is patterned and formed on the second substrate 21, following which the red filter layer 22R, the green filter layer 22G, and the blue filter layer 22B are each patterned and formed, for example. An unillustrated overcoat layer (planarizing layer) may be formed to cover an entire surface of the color filter layer 22, if necessary.

Then, the second electrode 23 is formed on the color filter layer 22 by using the above-described transparent conductive film.

Then, as illustrated in FIG. 4B, the spacers 25a and 25b are formed on selective regions (regions facing the black matrix layer BM) on the color filter layer 22. Specifically, the above-described photosensitive resin for example is formed on the second electrode 23, following which the photosensitive resin is selectively exposed by using a photomask to thereby form the spacers 25a and 25b. A difference in height of the spacers 25a and 25b may be given, for example, by performing the exposure twice. Specifically, the spacers 25a having the height h1 are first formed through a first exposure. Then, some of the spacers 25a are further subjected to exposure (second exposure), to thereby form the spacers 25b having the height h2. Alternatively, the spacer 25a and the spacer 25b having different heights may be formed through a single exposure by using a so-called halftone mask.

Then, as illustrated in FIG. 4C, the conductive film 24 made of the above-described material is formed, for example, over an entire surface of the second substrate 21, for example, by using the sputtering method.

Then, as illustrated in FIG. 4D, the region facing the spacer 25b of the conductive film 24 is selectively removed, for example, through the etching using the photolithography method. In this manner, the sealing substrate 20 is formed.

(Bonding (Sealing) Process)

Then, the device substrate 10 and the sealing substrate 20 each fabricated as described above are bonded to each other with the sealing layer 30 in between. Specifically, a sealing material is coated on the periphery (along an outer circumference of an effective display region) of the device substrate 10 or the sealing substrate 20. Then, for example, by using an ODF (One Drop Fill) method, a sealing resin is dropped, and the device substrate 10 and the sealing substrate 20 are press-bonded. In this manner, after the sealing resin is filled in the void S between the device substrate 10 and the sealing substrate 20, the sealing resin and the sealing material are cured. Thereby, the device substrate 10 and the sealing substrate 20 are bonded to each other (the device substrate 10 is sealed by the sealing substrate 20). As described above, the organic EL display unit 1 illustrated in FIG. 1 is completed.

[Function and Effect]

In the organic EL display unit 1, in accordance with a scanning signal and the like supplied from a drive circuit to be described later, a predetermined driving current is applied to the organic layer 16 via the first electrode 14 and the second electrode 23 for each pixel (organic EL elements 10R, 10G, and 10B). Thereby, in the luminescence layer of the organic layer 16, light is generated through the recombination of holes and electrons. Light (white light) generated from the organic layer 16 transmits through the resistive layer 17, the sealing layer 30, and the sealing substrate 20, and is taken out as display light. When passing through the color filter layer 22 of the sealing substrate 20, the light is taken out as color light of R, G, or B.

In this manner, in the top emission type organic EL display unit 1, white light generated from the organic layer 16 transmits through the second electrode 23, and passes through the color filter layer 22 to be taken out as color light of R, G, or B. Hence, the transparent conductive film, which is high in resistance, is used for the second electrode 23, causing a voltage drop and in turn, leading to unevenness in luminance in the panel surface. Also, variation in the wiring resistance in the panel surface is not negligible with an increase in size and the definition of the panel. This causes decrease in display quality.

To address such an issue, bringing the second electrode 23 into conduction with the auxiliary wiring layer 18 makes it possible to suppress the voltage drop. In the present embodiment, the auxiliary wiring layer 18 is provided facing the second electrode 23. Also, the second electrode 23 and the auxiliary wiring layer 18 are electrically connected to one another in the path A that includes the spacer 25a, and are electrically insulated from one another in the path B that includes the spacer 25b. Thereby, by the spacers 25a, a gap of the void S between the second electrode 23 and the auxiliary wiring layer 18 is mainly controlled and electrical conduction between the second electrode 23 and the auxiliary wiring layer 18 is secured.

Incidentally, for example, when a filling amount of the sealing resin is small to the capacity of the void S, air bubbles (non-filled region) may be generated in the sealing layer 30. Further, there may be a concern that the panel is excessively pressed by an atmospheric pressure to apply a load to the spacers, resulting in breakage of shapes of the spacers themselves and generation of cracks and breakage of wiring, etc.

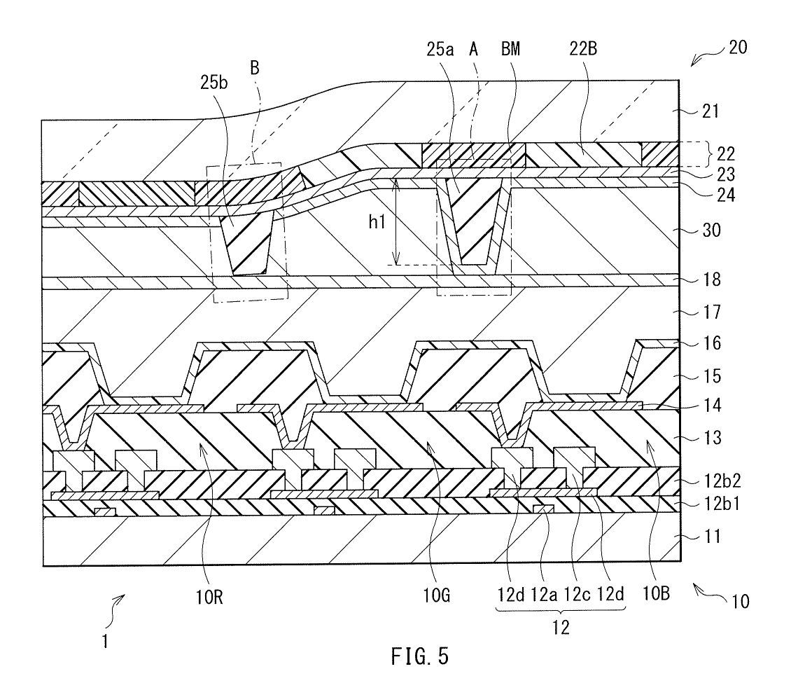

In the present embodiment, the spacer 25a and the spacer 25b having different heights from one another are provided. Thus, the capacity of the void S is flexibly matched in accordance with the filling amount of the sealing resin, and thereby generation of the above-described air bubbles is suppressed. Such a state is schematically illustrated in FIG. 5. Further, when the pressure is applied to a local region of the panel, a load due to the pressure is easily absorbed by the spacer 25b that is lower in height. Accordingly, the load applied to the spacer 25a is reduced, making it easier to keep a desired shape of each of the spacer 25a, the auxiliary wiring layer 18, the conductive film 24, and the like (occurrence of cracks and breakage is suppressed). Thereby, the gap of the void S is easily controlled, and the electrical connection between the auxiliary wiring layer 18 and the second electrode 23 is preferably secured, and a wiring resistance is effectively reduced.

Further, in the path B that includes the spacer 25b, the second electrode 23 and the auxiliary wiring layer 18 are electrically insulated from one another. Therefore, a wiring resistance of the second electrode 23 is difficult to be varied even if an influence of the above-described pressure, etc. is present and the spacer 25b is thus brought into contact with the auxiliary wiring layer 18 (FIG. 5) or not. That is, the variation in the wiring resistance of the second electrode 23 in the local region of the panel is suppressed.

In addition, since the filling amount of the sealing resin to the void S is easily controlled to be smaller in amount, it is possible to perform designing to reduce the amount used of the sealing resin.

As described above, in the present embodiment, the spacer 25a and the spacer 25b having different heights from one another are provided between the second electrode 23 and the auxiliary wiring layer 18, and the second electrode 23 and the auxiliary wiring layer 18 are electrically connected to one another in the path A that includes the spacer 25a, and are electrically insulated from one another in the path B that includes the spacer 25b. Thereby, while mechanical flexibility (durability) is kept, the wiring resistance is reduced and variation in the wiring resistance in the panel surface is suppressed. Accordingly, it is possible to improve reliability. Further, it is possible to reduce unevenness in a luminance distribution, and to improve a display quality.

Modification examples (modification examples 1 to 8) of the above-described example embodiment are described. The same components as those of the embodiment described above are denoted with the same reference numerals, and the descriptions are omitted as appropriate.

### Modification Example 1

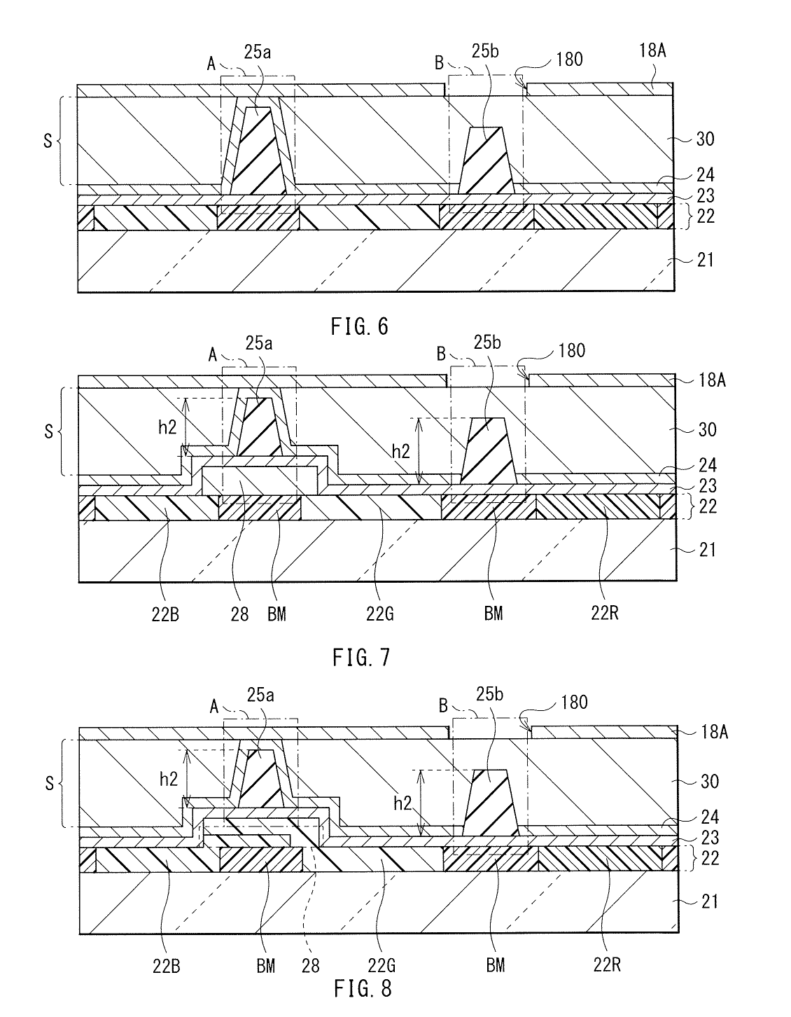

FIG. 6 illustrates a configuration of the sealing substrate and the auxiliary wiring layer according to modification example 1. As described above, the second electrode 23 and the auxiliary wiring layer 18 are electrically connected to one another in the path A including the spacer 25a, and are electrically insulated from one another in the path B including the spacer 25b. However, the path A and the path B may be formed based on configurations in modification examples 1 to 5 to be described hereinafter. In modification examples 1 to 5, the description is provided mainly on the configurations of the sealing substrate, the sealing layer, and the auxiliary wiring layer. The configuration of the device substrate 10 is same as that of the example embodiment described above.

In the present modification example, as with the embodiment described above, the spacers 25a and 25b are each made of an insulating material, and the conductive film 24 is formed to cover the surface of each of the spacers 25a and 25b. Further, the sealing resin is filled in the void S between the second electrode 23 and an auxiliary wiring layer (auxiliary wiring layer 18A), forming the sealing layer 30. However, in the present modification example, a region facing the spacer 25b of the auxiliary wiring layer (auxiliary wiring layer 18A) is selectively removed. That is, the auxiliary wiring layer 18A has an opening 180 (or, may be a groove) while facing the spacer 25b.

In this manner, the auxiliary wiring layer 18A may be selectively removed to secure the insulation of the path B. Also in this case, since the contact of the spacer 25b with the auxiliary wiring layer 18A due to a local pressure of the panel is suppressed, the same effects as those of the embodiment described above are achieved. Further, in the present modification example, patterning (the process of selectively removing the region facing the spacer 25b) of the conductive film 24 is unnecessary. On the other hand, the opening 180 may be formed at the time of patterning the auxiliary wiring layer 18A. Therefore, the number of manufacturing processes is reduced as compared to the embodiment described above.

In modification example 1, a case where the spacer 25b is formed on the second electrode 23 and formed separately from the auxiliary wiring layer 18A is given as an example. On the contrary, in the case where the spacer 25b is formed on the auxiliary wiring layer 18A, when a region facing the spacer 25b of the second electrode 23 is selectively removed, the same effect as that of the present modification example is obtained.

### Modification Example 2

FIG. 7 illustrates a configuration of the sealing substrate and the auxiliary wiring layer according to modification example 2. In the embodiment described above, the spacers 25a and 25b having different heights from one another are formed through a two-step exposure or an exposure using a halftone mask. However, as in the present modification example, such a difference in height of the spacers may be formed using a foundation layer 28. As the foundation layer 28, an insulating material may be used or a conductive material may be used. For example, after the foundation layer 28 is formed in a selective region on the color filter layer 22 (black matrix layer BM), the second electrode 23 and the conductive film 24 are formed. Alternatively, the second electrode 23, the foundation layer 28, and the conductive film 24 may be formed in this order. Thereafter, on the foundation layer 28 and in the selective region on the black matrix layer BM in which the foundation layer 28 is not formed, the spacers 25b are formed. By using the foundation layer 28 as described above, it is possible to form the difference in height without varying the heights of the spacers, and thereby to achieve the same effects as those of the embodiment described above. In addition, the number of processes of forming the spacer is reduced, or a halftone mask is unnecessary.

Alternatively, as the above-described foundation layer 28, a step, a laminated film, or the like previously formed on the second substrate 21 of the sealing substrate may be used. An example thereof is illustrated in FIG. 8. For example, the color filter layer 22 is formed on the second substrate 21, and the foundation layer 28 may be formed by utilizing the color filter layer 22. Specifically, the blue filter layer 22B and the green filter layer 22G may be formed on the black matrix layer BM in an overlapped manner to form a laminated film, and the thus-formed laminated film may be used as the foundation layer 28.

### Modification Example 3-1

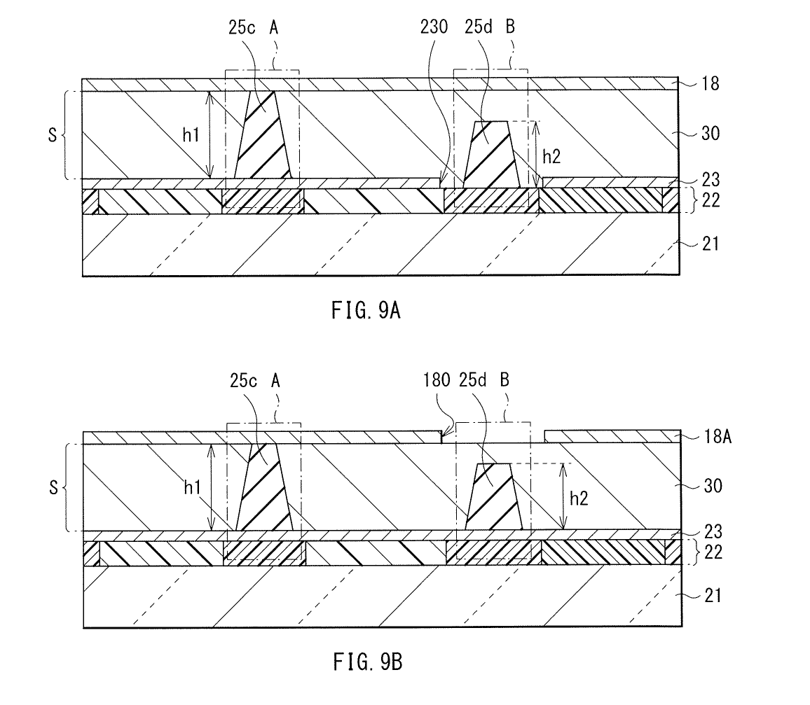

FIG. 9A illustrates a configuration of the sealing substrate and the auxiliary wiring layer according to modification example 3-1. In the above-described embodiment and modification examples 1 and 2, a case where the spacers 25a and 25b are each made of the insulating material is given as an example. However, as in the present modification example, spacers (spacers 25c and 25d) each made of a conductive material may be used. A constituent material for the spacers 25c and 25d may be a conductive resin, although other conductive materials may be used. As with the spacers 25a and 25b of the embodiment described above, the spacers 25c and 25d have different heights from one another, may be arranged in selective regions on the black matrix layer BM, for example. The sealing resin is filled in the void S between the second electrode 23 and the auxiliary wiring layer 18, forming the sealing layer 30.

In the present modification example, as described above, the spacers 25c and 25d are each made of the conductive material. Thus, the second electrode 23 and the auxiliary wiring layer 18 are each contacted with the spacer 25c in the path A including the spacer 25c having the height h1. Thereby, the electrical conduction between the second electrode 23 and the auxiliary wiring layer 18 is secured.

On the other hand, in the path B that includes the spacer 25d having the height h2, the insulation is secured as follows. In the present modification example, a region facing the spacer 25d of the second electrode 23 is selectively removed (the second electrode 23 has an opening 230 in the region facing the spacer 25d). For example, to form the spacers 25c and 25d after the formation of the second electrode 23, the opening 230 is first formed in the formation process of the second electrode 23, following which exposure is carried out so that the spacer 25d is formed in the opening 230 in the formation process of the spacers 25c and 25d. Thereby, the insulation between the second electrode 23 and the auxiliary wiring layer 18 is secured in the path B including the spacer 25d. Accordingly, even if the spacer 25d is brought into contact with the auxiliary wiring layer 18, the electrical conduction between the auxiliary wiring layer 18 and the second electrode 23 is suppressed, and the same effects as those of the embodiment described above are achieved.

### Modification Example 3-2

FIG. 9B illustrates a configuration of the sealing substrate and the auxiliary wiring layer according to modification example 3-2. In the modification example 3-1, the spacers 25c and 25d each made of the conductive material are used, and the region facing the spacer 25d of the second electrode 23 is selectively removed. However, as in the present modification example, the auxiliary wiring layer (auxiliary wiring layer 18A) may be selectively removed (the auxiliary wiring layer 18A may have the opening 180). Further, although not illustrated in the drawings, a region facing the spacer 25d may be selectively removed for both of the second electrode 23 and the auxiliary wiring layer 18A. Even in the configuration of the present modification example, the electrical insulation between the second electrode 23 and the auxiliary wiring layer 18A is secured in the path B including the spacer 25d.

### Modification Example 4-1

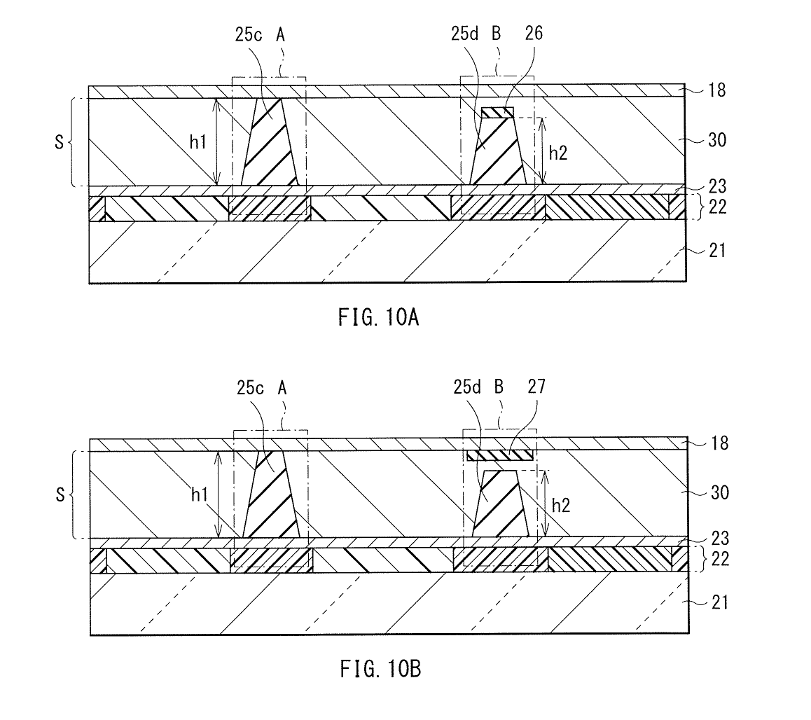

FIG. 10A illustrates a configuration of the sealing substrate and the auxiliary wiring layer according to modification example 4-1. In the present modification example, the spacers 25c and 25d each made of the conductive material are used as in the modification examples 3-1 and 3-2. The spacers 25c and 25d have different heights from one another as with the spacers 25a and 25b of the embodiment described above, and may be arranged in the selective regions on the black matrix layer BM. Further, the second electrode 23 and the auxiliary wiring layer 18 are each brought into contact with the spacer 25c in the path A that includes the spacer 25c having the height h1. Thereby, the electrical conduction between the second electrode 23 and the auxiliary wiring layer 18 is secured.

However, in the present modification example, the insulation is secured as follows in the path B including the spacer 25d having the height h2. That is, an insulating film 26 is formed on a surface facing the auxiliary wiring layer 18 of the spacer 25d. As the insulating film 26, a photosensitive resin such as photoresist may be preferably used to thereby omit the etching process at the time of patterning. Further, the insulating film 26 may be preferably formed to cover at least an upper surface of the spacer 25d. Through the formation of the insulating film 26, the insulation between the second electrode 23 and the auxiliary wiring layer 18 is secured in the path B including the spacer 25d. Accordingly, even if the spacer 25d is brought into contact with the auxiliary wiring layer 18, the electrical conduction between the auxiliary wiring layer 18 and the second electrode 23 is suppressed, and the same effects as those of the embodiment described above are achieved.

### Modification Example 4-2

FIG. 10B illustrates a configuration of the sealing substrate and the auxiliary wiring layer according to modification example 4-2. In the modification example 4-1 described above, the spacers 25c and 25d each made of the conductive material are used, and the insulating film 26 is formed on the surface facing the auxiliary wiring layer 18 of the spacer 25d. However, as in the present modification example, an insulating film 27 may be formed on a surface facing the spacer 25d of the auxiliary wiring layer 18. Further, although not illustrated in the drawings, the insulating films 26 and 27 may be formed on both the second electrode 23 and the auxiliary wiring layer 18 (on respective facing surfaces thereof). Even in the configuration of the present modification example, the electrical insulation between the second electrode 23 and the auxiliary wiring layer 18A is secured in the path B including the spacer 25d.

### Modification Example 5

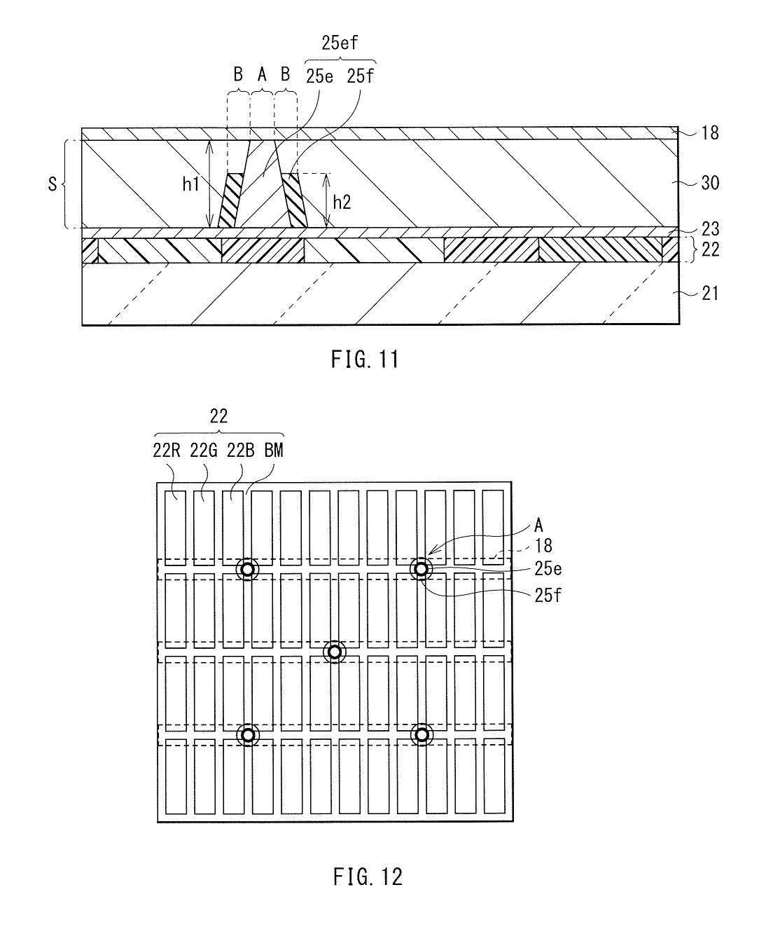

FIG. 11 illustrates a configuration of the sealing substrate and the auxiliary wiring layer according to modification example 5. FIG. 12 illustrates an example of an arrangement configuration of the spacers and the auxiliary wiring layer according to modification example 5. In the embodiment and the like described above, a case where two types of spacers having different heights from one another are arranged in the void S is described. However, as in the present modification example, a single type of spacer having a step (difference in height) may be arranged. That is, a spacer (spacer 25ef) in which the above-described spacers 25a and 25b (25c and 25d) are integrated may be used. Specifically, the spacer 25ef has a configuration in which a spacer section 25e and a spacer section 25f are integrated. For example, as with the spacer 25c of the modification examples 3-1 to 4-2, the spacer section 25e may be made of a conductive material, and has the height h1. For example, as with the spacer 25b of modification examples 1 and 2 and the embodiment described above, the spacer 25f may be made of an insulating material, and has the height h2. The spacer sections 25e and 25f are so integrally formed that the spacer section 25f surrounds the spacer section 25e, for example.

Also in the present modification example, the spacer 25ef has the spacer section 25e having the height h1 and the spacer section 25f having the height h2. Therefore, the spacer section 25e controls the gap of the void S, and secures the electrical connection between the second electrode 23 and the auxiliary wiring layer 18. On the other hand, the spacer section 25f absorbs the load due to the local pressure and keeps the shapes of the spacer section 25e, the auxiliary wiring layer 18, and the like. Further, the electrical insulation between the second electrode 23 and the auxiliary wiring layer 18 is secured in the path B that includes the spacer section 25f, and therefore variation in the wiring resistance is suppressed. Accordingly, the same effects as those of the embodiment described above are achieved.

### Modification Example 6

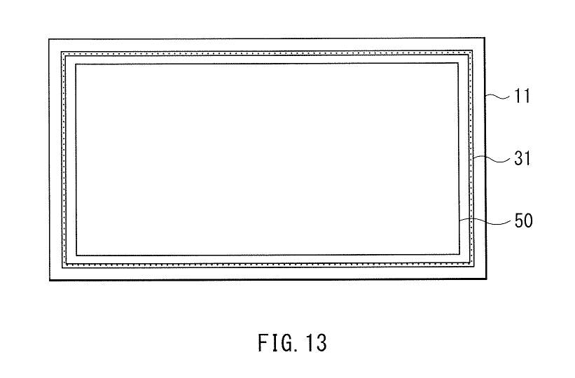

FIG. 13 is a schematic view for describing an arrangement example of the spacers according to modification example 6. In the above-described organic EL display unit 1, a seal section 31 is formed for example, on the periphery of the effective display region (display region 50) of the first substrate 11 (or, the second substrate 21 of the sealing substrate 20) of the device substrate 10. The seal section 31 serves as an outer frame (dam member) of the above-described sealing layer 30. The sealing resins are filled in the space (void S) surrounded by the seal section 31 and the device substrate 10 as well as the sealing substrate 20 to seal the elements. As described above, the arrangement of the spacers 25a and 25b may be set on an as-necessary basis in consideration of the mechanical flexibility of the panel and the wiring resistance, although the spacers 25a and 25b may also be arranged as in the present modification example. Specifically, by decreasing the density of the spacers in the vicinity of the seal section 31, adhesiveness in the seal section 31 is improved. This may be achieved, for example, by reducing the locations at which the spacers 25a and 25b are provided in the vicinity of the seal section 31 as compared to those in the display region, or increasing the locations at which the spacers 25b having the height h2 are provided relatively as compared to those of the spacer 25a having the height h1.

### Modification Example 7

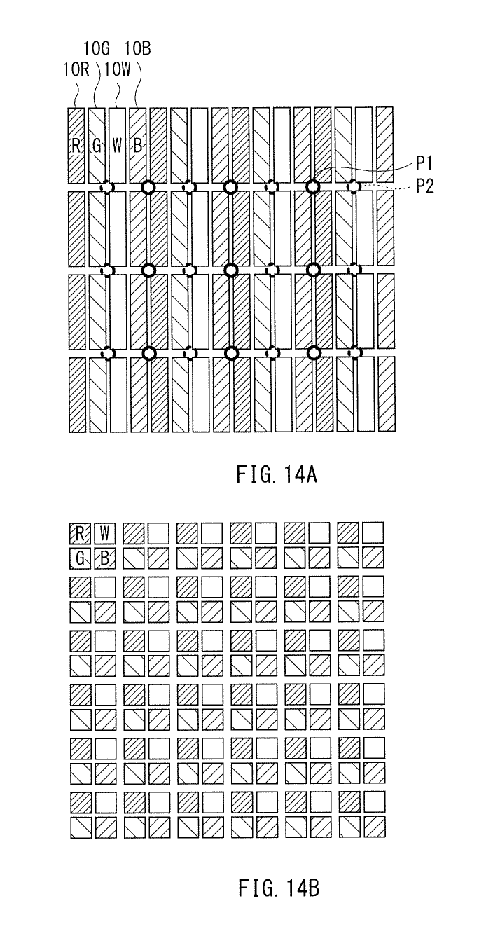

FIG. 14A is a schematic view for describing an arrangement example of the spacers according to modification example 7. In the embodiment and the like described above, a case where one pixel includes three color sub-pixels (organic EL elements 10R, 10G, and 10B) of R, G, and B is given as an example. However, one pixel may include four sub-pixels to which a sub-pixel (organic EL element 10W) of W (white) is added. In this case, as illustrated in FIG. 14A, the spacers (the spacer 25a or the spacer 25b or both) may be preferably arranged in a position P1 in the vicinity of the sub-pixels (organic EL elements 10R and 10B) each corresponding to a color which is low in visibility. On the other hand, preferably, the spacer may not be arranged, or only the spacer (spacer 25b) lower in height may be arranged in a position P2 in the vicinity of the sub-pixels (organic EL elements 10G and 10W) each corresponding to a color which is high in visibility relatively. Since the spacer having the higher height (the spacer 25a) has the larger installation area, leakage of light may easily occur when such spacer is arranged in a region having high visibility in particular. Therefore, such arrangement of the spacers is preferable in that providing one of the spacers 25a and 25b at the position P1, or providing the spacer 25a and the spacer 25b at the position P1 and the position P2, respectively, makes it possible to reduce the leakage of light as described above. When the pixels are arranged as illustrated in FIG. 14B, the positions of the spacers 25a and 25b are not particularly limited from the viewpoint of the above-described light leakage.

### Modification Example 8

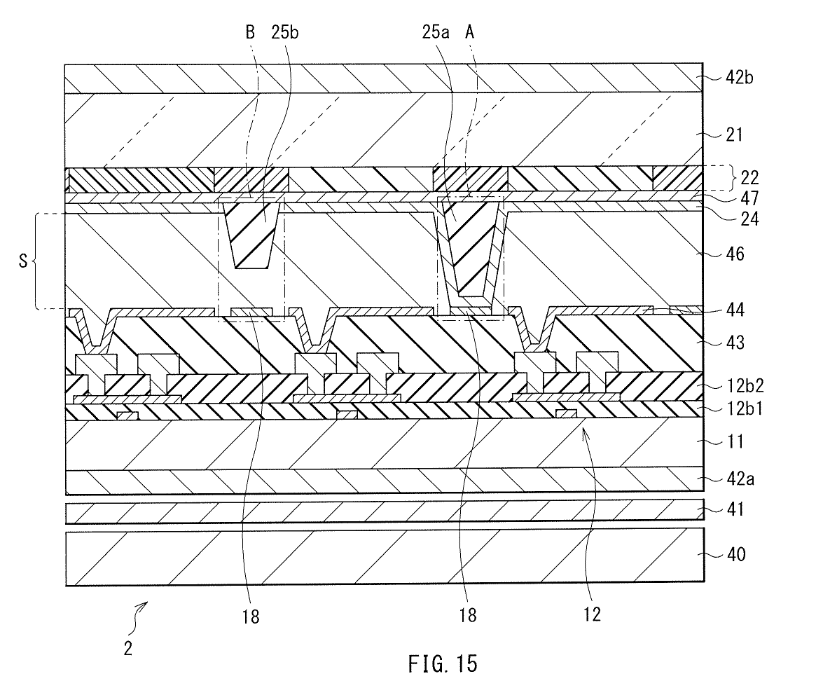

FIG. 15 illustrates a cross-sectional configuration of a display unit (liquid crystal display unit 2) according to modification example 8. In the embodiment and the like described above, the organic EL display unit 1 is given as an example, although embodiments of the present disclosure are applicable also to the liquid crystal display unit 2 as described in the present modification example. In the liquid crystal display unit 2, a polarizer 42a may be attached to a rear surface of the first substrate 11, for example, and a backlight 40 may be arranged below the polarizer 42a. A diffuser 41 is provided between the backlight 40 and the polarizer 42a. Further, the TFTs 12 are formed on the first substrate 11, and a planarizing film 43 is formed to cover the TFTs 12. On the planarizing film 43, the first electrodes 44 are arranged for respective pixels, and are connected to the respective TFTs 12 through contact holes of the planarizing film 43. On the other hand, a polarizer 42b is attached to a light-emission side of the second substrate 21. Further, the color filter layer 22 is formed on a surface on the first substrate 11 side of the second substrate 21, and a second electrode 47 is formed adjacent to the color filter layer 22.

In the liquid crystal display unit 2, a liquid crystal layer 46 is sealed in the void S between the first substrate 11 and the second substrate 21 (between the first electrodes 44 and the second electrode 47). As in the embodiment described above, the spacers 25a and 25b are arranged in the void S. That is, in the present modification example, the gap of the liquid crystal layer 46 is controlled by the spacers 25a and 25b (mainly, the spacer 25a).

Also in the liquid crystal display unit 2, the second electrode 47 is made of the transparent conductive film and has a high resistance. Therefore, the second electrode 47 is electrically connected to the auxiliary wiring layer 18, thereby reducing the wiring resistance. In the modification example 8, for example, the auxiliary wiring layer 18 may be formed on the first substrate 11 serving as a driving substrate and may be formed in the same layer as the first electrode 44 on the planarizing film 43. However, this is not limitative, and the auxiliary wiring layer 18 may be formed in the same layer as the TFTs 12. Also in the present modification example, the auxiliary wiring layer 18 may be patterned to have a stripe pattern or to have a lattice pattern, so long as the wiring layer 18 is arranged in the region facing the black matrix layer BM. As with the embodiment described above, the auxiliary wiring layer 18 and the second electrode 23 are electrically connected to one another in the path A that includes the spacer 25a, and are electrically insulated from one another in the path B that includes the spacer 25b. Specifically, as with the embodiment described above, the conductive film 24 is provided to cover the surface of each of the spacers 25a and 25b, and the region facing the spacer 25b of the conductive film 24 is selectively removed.

As described above, the effects of keeping the mechanical flexibility and reducing the wiring resistance derived from the spacers 25a and 25b are applicable also to a liquid crystal sealing structure. In addition, embodiments of the technology are widely applicable to any field in which a sealing structure using spacers is used.

[Overall Configuration of Display Unit and Pixel Circuit Configuration]

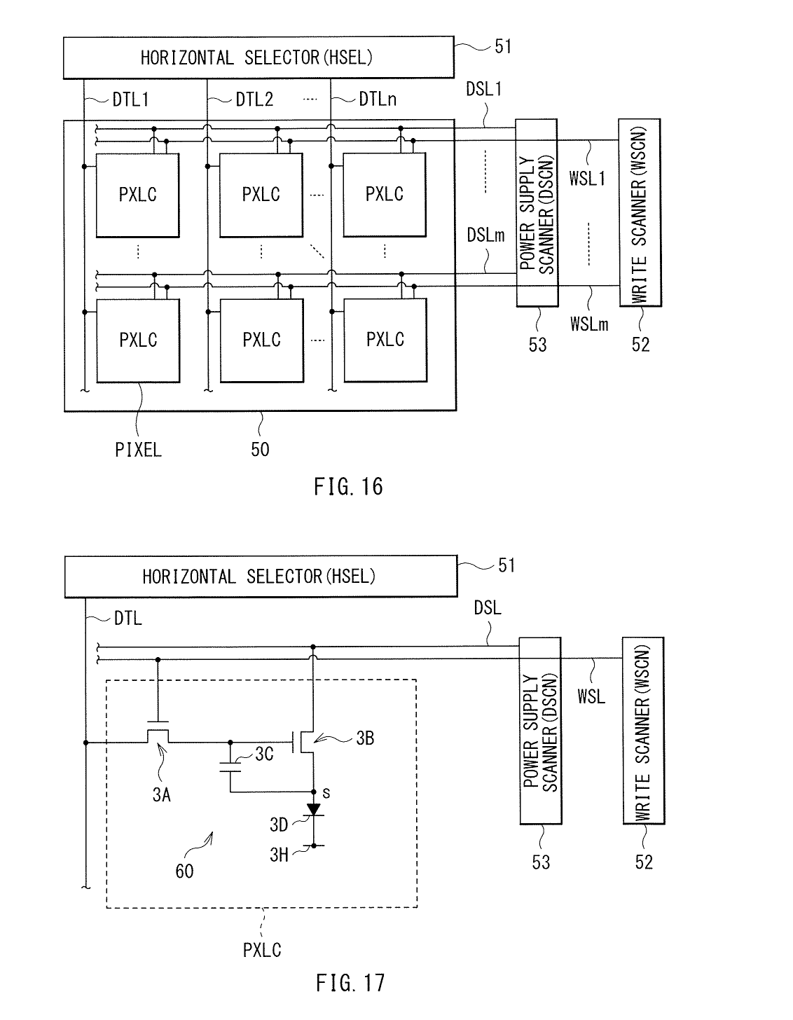

An overall configuration and a pixel circuit configuration of the organic EL display unit (hereinafter, simply referred to as “display unit”) according to any of the above-described embodiments and the like are described. FIG. 16 illustrates an overall configuration including peripheral circuits of the display unit used as the organic EL display. For example, the display region 50, in which a plurality of pixels PXLC including the organic EL elements are arranged in a matrix form, is formed on the first substrate 11. Further, a horizontal selector (HSEL) 51 as a signal line drive circuit, a write scanner (WSCN) 52 as a scanning line drive circuit, and a power supply scanner (DSCN) 53 as a power supply line drive circuit are provided around the display region 50.

In the display region 50, a plurality of (integer n-number of) signal lines DTL1 to DTLn are arranged in a column direction, and a plurality of (integer m-number of) scanning lines WSL1 to WSLm and power supply lines DSL1 to DSLm are arranged in a row direction. Further, in each intersection of each signal line DTL and each scanning line WSL, the pixel PXLC (one of the pixels corresponding to R, G, and B) is provided. Each signal line DTL is connected to the horizontal selector 51, and an image signal is supplied to each signal line DTL from the horizontal selector 51. Each scanning line WSL is connected to the write scanner 52, and a scanning signal (selection pulse) is supplied to each scanning line WSL from the write scanner 52. Each power supply line DSL is connected to the power supply scanner 53, and a power supply signal (control pulse) is supplied to each power supply line DSL from the power supply scanner 53.

FIG. 17 illustrates a specific example of a circuit configuration of the pixel PXLC. Each pixel PXLC has the pixel circuit 60 including the organic EL element 3D. The pixel circuit 60 is an active drive circuit having a sampling transistor 3A, a driving transistor 3B, a holding capacitor 3C, and the organic EL element 3D. The transistor 3A (or, the transistor 3B) corresponds to the TFT 12 of any of the embodiment and the modification examples described above. Further, the organic EL element 3D corresponds to one of the organic EL elements 10R, 10G, and 10B of any of the embodiment and the modification examples described above.

In the sampling transistor 3A, a gate is connected to the corresponding scanning line WSL, one of a source and a drain is connected to the corresponding signal line DTL, and the other of the source and the drain is connected to a gate of the driving transistor 3B. In the driving transistor 3B, a drain is connected to the corresponding power supply line DSL, and a source is connected to an anode of the organic EL element 3D. Further, a cathode of the organic EL element 3D is connected to a ground wiring 3H. The ground wiring 3H is wired commonly to all the pixels PXLC. The holding capacitor 3C is arranged between the source and the gate of the driving transistor 3B.

The sampling transistor 3A is brought into conduction in accordance with the scanning signal (selection pulse) supplied from the scanning line WSL. Thereby, the sampling transistor 3A samples a signal potential of the image signal supplied from the signal line DTL, and holds the sampled signal potential in the holding capacitor 3C. The driving transistor 3B receives the supply of a current from the power supply line DSL set at a predetermined first potential (not illustrated). Further, the driving transistor 3B supplies a drive current to the organic EL element 3D in accordance with the signal potential held in the holding capacitor 3C. Through the drive current supplied from the driving transistor 3B, the organic EL element 3D emits light at a luminance corresponding to the signal potential of the image signal.

In the above-described circuit configuration, the sampling transistor 3A is brought into conduction in accordance with the scanning signal (selection pulse) supplied from the scanning line WSL. Thereby, the signal potential of the image signal supplied from the signal line DTL is sampled and held by the holding capacitor 3C. Further, a current is supplied to the driving transistor 3B from the power supply line DSL set at the first potential. In accordance with the signal potential held in the holding capacitor 3C, the drive current is supplied to the organic EL element 3D (each of the organic EL elements of red, green, and blue). Further, through the supplied drive current, each of the organic EL elements 3D emits light at a luminance corresponding to the signal potential of the image signal. Thereby, in the display unit, an image is displayed on the basis of the image signal.

### Application Example

Hereinafter, application examples to electronic apparatus of the organic EL display unit or the liquid crystal display unit (hereinafter, referred to as a display unit) according to any of the embodiments and the like described above are described. Examples of the electronic apparatus may include a television set, a digital camera, a notebook personal computer, a mobile phone, a portable terminal unit such as a smartphone, a video camera, and the like. In other words, the above-described display unit is applicable to electronic apparatus in any field, in which an image signal input from the outside or an image signal generated in the inside is displayed as an image or a picture.

(Module)

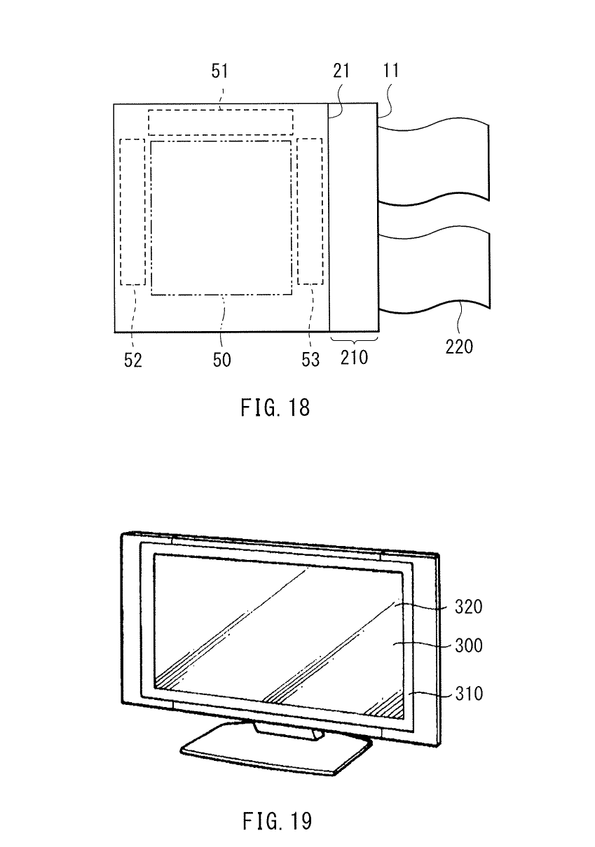

As a module as illustrated in FIG. 18, for example, any of the above-described display units is integrated into various sorts of electronic apparatus, such as those of application examples 1 to 5 to be hereinafter described. In the module, for example, a region 210 exposed from the second substrate 21 is provided on one side of the first substrate 11. Further, wirings of the horizontal selector 51, the write scanner 52, and the power supply scanner 53 are extended to form an external connection terminal (not illustrated) in the exposed region 210. In the external connection terminal, an FPC (Flexible Printed Circuit) 220 for inputting and outputting signals may be provided.

### Application Example 1

FIG. 19 illustrates an appearance of a television set. The television set has, for example, an image display screen section 300 including a front panel 310 and a filter glass 320. The image display screen section 300 corresponds to the above-described display unit.

### Application Example 2

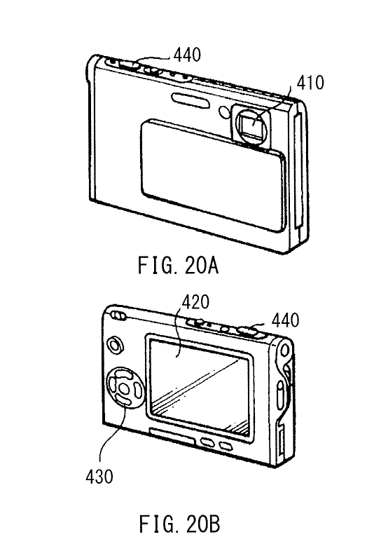

FIGS. 20A and 20B each illustrate an appearance of a digital camera. The digital camera has, for example, a flash light emitting section 410, a display section 420, a menu switch 430, and a shutter button 440. The display section 420 corresponds to the above-described display unit.

### Application Example 3

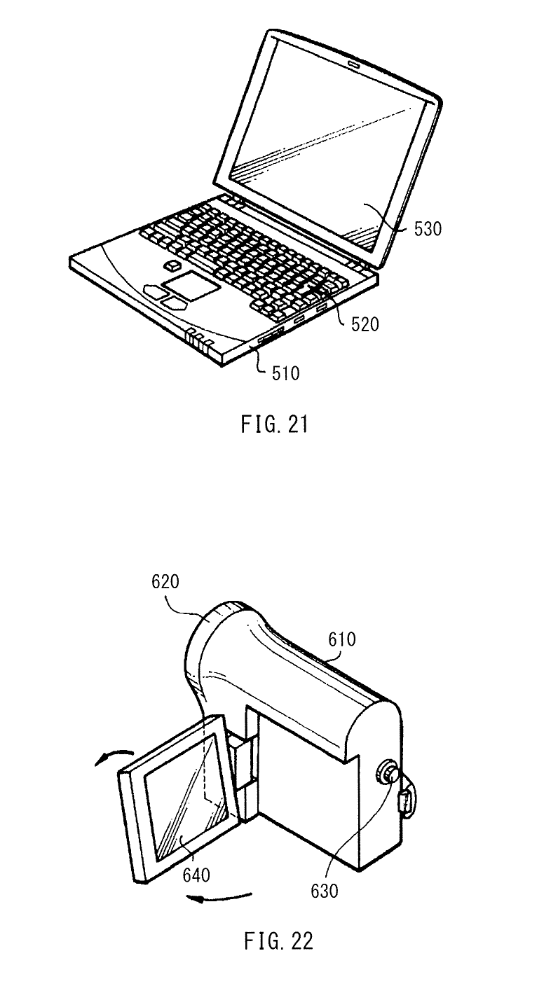

FIG. 21 illustrates an appearance of a notebook personal computer. The notebook personal computer has, for example, a main body 510, a keyboard 520 for an input operation of characters, etc., and a display section 530 that displays an image. The display section 530 corresponds to the above-described display unit.

### Application Example 4

FIG. 22 illustrates an appearance of a video camera. The video camera has, for example, a main body section 610, a shooting lens 620 provided on a front side face of the main body section 610, a start/stop switch 630 upon shooting, and a display section 640. The display section 640 corresponds to the above-described display unit.

### Application Example 5

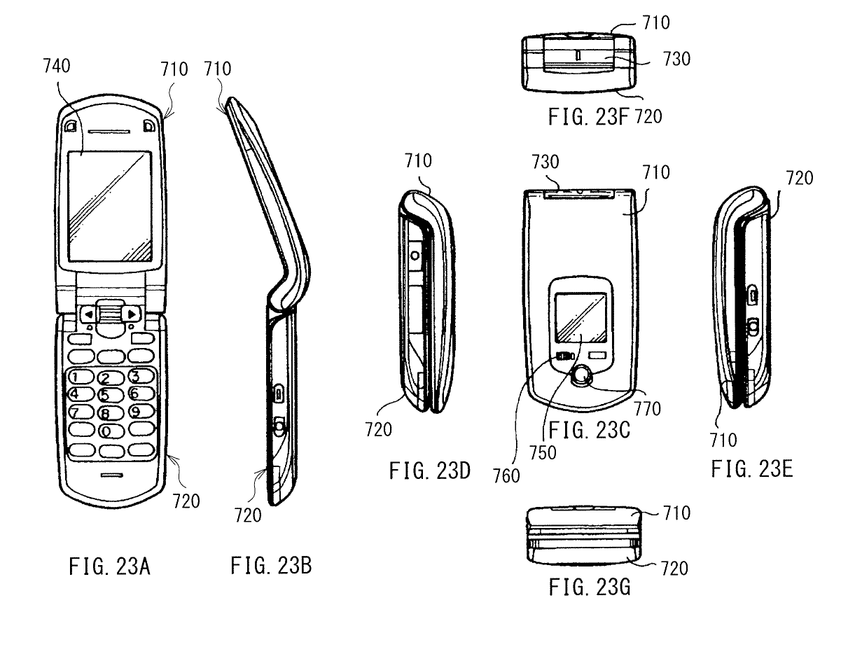

FIG. 23 illustrates an appearance of a mobile phone. The mobile phone has a configuration in which, for example, an upper body 710 and a lower body 720 are connected by a connection section (hinge part) 730, and has a display 740, a sub-display 750, a picture light 760, and a camera 770. The display 740 or the sub-display 750 corresponds to the above-described display unit.

### Application Example 6

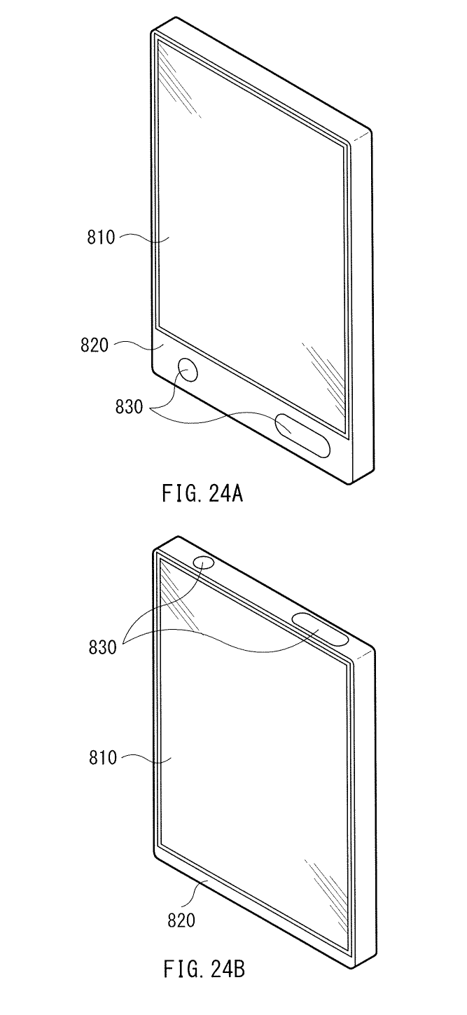

FIGS. 24A and 24B each illustrate an appearance of a smartphone. The smartphone has, for example, a display section 810 (corresponds to the above-described display unit) and a non-display section (housing) 820, and an operating section 830. The operating section 830 may be provided on a front face of the non-display section 820 (FIG. 24A), or on an upper face (FIG. 24B).

As described above, the present disclosure is described with reference to the example embodiment, the modification examples, and the application examples. However, the present disclosure is not limited to the embodiments and the like described above, and may be variously modified. For example, in the embodiment and the like described above, a case where the spacers 25a and 25b are formed on the sealing substrate 20 side is described as an example. However, the spacers 25a and 25b may be formed on the device substrate 10 side.

Further, in the embodiment and the like described above, the auxiliary wiring layer 18 is provided above the device substrate 10 (resistive layer 17), and the second electrode 23 is provided on the sealing substrate 20. However, the second electrode 23 may be provided above the device substrate 10 and the auxiliary wiring layer 18 may be provided on the sealing substrate 20.

Further, in the embodiment and the like described above, the color filter layer 22 is provided on the sealing substrate 20. However, the color filter layer 22 may be provided on the device substrate 10.

In addition, in the embodiment and the like described above, a so-called solid sealing structure is described as an example in which the sealing resin is filled in the void S between the device substrate 10 and the sealing substrate 20 in the organic EL display unit 1. However, the present disclosure is not limited thereto, and may be applicable also to the case of a so-called hollow sealing. Note that, because embodiments of the present disclosure are capable of suppressing the generation air bubbles at the time of filling the sealing resin in the void S, embodiments of the technology are more advantageous than application to a hollow sealing structure, without limitation.

Further, in the embodiment and the like described above, a case of an active-matrix type display unit is described. However, embodiments of the present disclosure are also applicable to a passive-matrix type display unit. In addition, the configuration of the pixel drive circuit for driving the active-matrix type display unit is not limited to that described in the above-described embodiments and the like, and capacitors, transistors, and the like may be added thereto on an as-needed basis.

Further, in the embodiment and the like described above, the top emission type organic EL display unit is described as an example. However, the organic EL display unit according to any of the embodiments of the present disclosure is applicable also to a bottom emission type organic EL display unit. In particular, the organic EL display unit is applicable preferably to a case where an upper electrode is configured by a conductive film having high resistance, such as a transparent conductive film.

In addition, in the embodiment and the like described above, two types of spacers having different heights from one another are used. However, three or more types of spacers may be used to vary the heights in a stepwise fashion.

Furthermore, the technology encompasses any possible combination of some or all of the various embodiments described herein and incorporated herein.

It is possible to achieve at least the following configurations from the above-described example embodiments of the disclosure.

(1) A display unit including:

a plurality of first electrodes provided for respective pixels;

a display function layer provided on the first electrodes;

a second electrode configured to apply, together with the first electrodes, a drive voltage to the display function layer;

a third electrode disposed facing the second electrode, and electrically connected to the second electrode;

a first spacer arranged between the second electrode and the third electrode; and

a second spacer arranged between the second electrode and the third electrode, and having a height that is lower than a height of the first spacer,

wherein the second electrode and the third electrode are electrically connected to one another in a path that includes the first spacer, and are electrically insulated from one another in a path that includes the second spacer.

(2) The display unit according to (1), further including a conductive film,

wherein each of the first spacer and the second spacer is made of an insulating material, and at least a part of a surface of each of the first spacer and the second spacer is covered with the conductive film.

(3) The display unit according to (2), wherein a region facing the second spacer of the conductive film is selectively removed.
(4) The display unit according to (2) or (3), wherein a region facing the second spacer of one of the second electrode and the third electrode is selectively removed.
(5) The display unit according to (1), wherein each of the first spacer and the second spacer is made of a conductive material.
(6) The display unit according to (5), wherein a region facing the second spacer of one of the second electrode and the third electrode is selectively removed.
(7) The display unit according to (5) or (6), further including an insulating film provided on a surface facing the third electrode of the second spacer, on a surface facing the second spacer of the third electrode, or on each of the facing surfaces of the second spacer and the third electrode.
(8) The display unit according to any one of (1) to (7), wherein a difference in the height between the first spacer and the second spacer is formed by a thickness of a foundation layer of the first spacer.
(9) The display unit according to (8), wherein the foundation layer is a laminated film including two or more layers of a color filter layer and a black matrix layer.
(10) The display unit according to any one of (1) to (9), wherein the first spacer and the second spacer are formed integrally.
(11) The display unit according to any one of (1) to (10), wherein a density of the arrangement of each of the first spacer and the second spacer is lower in a peripheral region of an effective display region that includes the pixels than in the effective display region.
(12) The display unit according to any one of (1) to (11), wherein the display function layer is an organic electroluminescence layer, and a sealing resin is filled between the second electrode and the third electrode.
(13) The display unit according to any one of (1) to (11), wherein the display function layer is a liquid crystal layer.
(14) A method of manufacturing a display unit, the method including:

forming a plurality of first electrodes for respective pixels;

forming a display function layer;

forming a second electrode configured to apply, together with the first electrodes, a drive voltage to the display function layer;

forming a third electrode disposed facing the second electrode, and electrically connected to the second electrode; and

forming a first spacer and a second spacer between the second electrode and the third electrode, the second spacer having a height that is lower than a height of the first spacer,

wherein the second electrode and the third electrode are electrically connected to one another in a path that includes the first spacer, and are electrically insulated from one another in a path that includes the second spacer.

(15) The method of manufacturing the display unit according to (14), wherein in the forming the first spacer and the second spacer,

each of the first spacer and the second spacer is formed by an insulating material,

a conductive film is formed to cover a surface of each of the formed first spacer and the formed second spacer, and

a region facing the second spacer of the formed conductive film is selectively removed.

(16) The method of manufacturing the display unit according to (14) or (15), wherein

in the forming the first spacer and the second spacer, each of the first spacer and the second spacer is formed by an insulating material, and a conductive film is formed to cover a surface of each of the formed first spacer and the formed second spacer, and

in one of the forming the second electrode and the forming the third electrode, a region facing the second spacer of one of the second electrode and the third electrode is selectively removed.

(17) The method of manufacturing the display unit according to (14), wherein

in the forming the first spacer and the second spacer, each of the first spacer and the second spacer is formed by a conductive material, and

in one of the forming the second electrode and the forming the third electrode, a region facing the second spacer of one of the second electrode and the third electrode is selectively removed.

(18) The method of manufacturing the display unit according to (14) or (17), further including forming an insulating film on a surface facing the third electrode of the second spacer, on a surface facing the second spacer of the third electrode, or on each of the facing surfaces of the second spacer and the third electrode,

wherein in the forming the first spacer and the second spacer, each of the first spacer and the second spacer is formed by a conductive material.

(19) An electronic apparatus provided with a display unit, the display unit including:

a plurality of first electrodes provided for respective pixels;

a display function layer provided on the first electrodes;

a second electrode configured to apply, together with the first electrodes, a drive voltage to the display function layer;

a third electrode disposed facing the second electrode, and electrically connected to the second electrode;

a first spacer arranged between the second electrode and the third electrode; and

a second spacer arranged between the second electrode and the third electrode, and having a height that is lower than a height of the first spacer,

wherein the second electrode and the third electrode are electrically connected to one another in a path that includes the first spacer, and are electrically insulated from one another in a path that includes the second spacer.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A display unit comprising:
a plurality of first electrodes provided for respective pixels;
a display function layer provided on the first electrodes;
a second electrode configured to apply, together with the first electrodes, a drive voltage to the display function layer;
a third electrode disposed facing the second electrode, and electrically connected to the second electrode;
a first spacer arranged between the second electrode and the third electrode; and
a second spacer arranged between the second electrode and the third electrode, and having a height that is lower than a height of the first spacer,
wherein the second electrode and the third electrode are electrically connected to one another in a path that includes the first spacer, and are electrically insulated from one another in a path that includes the second spacer.

2. The display unit according to claim 1, further comprising a conductive film,
wherein each of the first spacer and the second spacer is made of an insulating material, and at least a part of a surface of each of the first spacer and the second spacer is covered with the conductive film.

3. The display unit according to claim 2, wherein a region facing the second spacer of the conductive film is selectively removed.

4. The display unit according to claim 2, wherein a region facing the second spacer of one of the second electrode and the third electrode is selectively removed.

5. The display unit according to claim 1, wherein each of the first spacer and the second spacer is made of a conductive material.

6. The display unit according to claim 5, wherein a region facing the second spacer of one of the second electrode and the third electrode is selectively removed.

7. The display unit according to claim 5, further comprising an insulating film provided on a surface facing the third electrode of the second spacer, on a surface facing the second spacer of the third electrode, or on each of the facing surfaces of the second spacer and the third electrode.

8. The display unit according to claim 1, wherein a difference in the height between the first spacer and the second spacer is formed by a thickness of a foundation layer of the first spacer.

9. The display unit according to claim 8, wherein the foundation layer is a laminated film including two or more layers of a color filter layer and a black matrix layer.

10. The display unit according to claim 1, wherein the first spacer and the second spacer are formed integrally.

11. The display unit according to claim 1, wherein a density of the arrangement of each of the first spacer and the second spacer is lower in a peripheral region of an effective display region that includes the pixels than in the effective display region.

12. The display unit according to claim 1, wherein the display function layer is an organic electroluminescence layer, and a sealing resin is filled between the second electrode and the third electrode.

13. The display unit according to claim 1, wherein the display function layer is a liquid crystal layer.

14. A method of manufacturing a display unit, the method comprising:
forming a plurality of first electrodes for respective pixels;
forming a display function layer;
forming a second electrode configured to apply, together with the first electrodes, a drive voltage to the display function layer;
forming a third electrode disposed facing the second electrode, and electrically connected to the second electrode; and
forming a first spacer and a second spacer between the second electrode and the third electrode, the second spacer having a height that is lower than a height of the first spacer,
wherein the second electrode and the third electrode are electrically connected to one another in a path that includes the first spacer, and are electrically insulated from one another in a path that includes the second spacer.

15. The method of manufacturing the display unit according to claim 14, wherein in the forming the first spacer and the second spacer,
each of the first spacer and the second spacer is formed by an insulating material,
a conductive film is formed to cover a surface of each of the formed first spacer and the formed second spacer, and
a region facing the second spacer of the formed conductive film is selectively removed.

16. The method of manufacturing the display unit according to claim 14, wherein
in the forming the first spacer and the second spacer, each of the first spacer and the second spacer is formed by an insulating material, and a conductive film is formed to cover a surface of each of the formed first spacer and the formed second spacer, and
in one of the forming the second electrode and the forming the third electrode, a region facing the second spacer of one of the second electrode and the third electrode is selectively removed.

17. The method of manufacturing the display unit according to claim 14, wherein
in the forming the first spacer and the second spacer, each of the first spacer and the second spacer is formed by a conductive material, and
in one of the forming the second electrode and the forming the third electrode, a region facing the second spacer of one of the second electrode and the third electrode is selectively removed.

18. The method of manufacturing the display unit according to claim 14, further comprising forming an insulating film on a surface facing the third electrode of the second spacer, on a surface facing the second spacer of the third electrode, or on each of the facing surfaces of the second spacer and the third electrode,
wherein in the forming the first spacer and the second spacer, each of the first spacer and the second spacer is formed by a conductive material.

19. An electronic apparatus provided with a display unit, the display unit comprising:
a plurality of first electrodes provided for respective pixels;
a display function layer provided on the first electrodes;
a second electrode configured to apply, together with the first electrodes, a drive voltage to the display function layer;
a third electrode disposed facing the second electrode, and electrically connected to the second electrode;
a first spacer arranged between the second electrode and the third electrode; and
a second spacer arranged between the second electrode and the third electrode, and having a height that is lower than a height of the first spacer,
wherein the second electrode and the third electrode are electrically connected to one another in a path that includes the first spacer, and are electrically insulated from one another in a path that includes the second spacer.
